(19) United States
(12) Patent Application Publication
(10) Pub. No.: US 2022/0367814 A1
(43) Pub. Date: Nov. 17, 2022

(54) PHOTOACTIVE COMPOSITION

(71) Applicant: RAYNERGY TEK INC., HSINCHU (TW)

(72) Inventors: ANDROMACHI MALANDRAKI, BISCHOFSHEIM (DE); LICHUN CHEN, SOUTHAMPTON (GB)

(21) Appl. No.: 17/595,297

(22) PCT Filed: May 4, 2020
(86) PCT No.: PCT/EP2020/062233

§ 371 Date: Nov. 12, 2021

(30) Foreign Application Priority Data
May 6, 2019 (EP) 19172683.5

(51) Int. Cl. H01L 51/00; C08L 65/00

(52) U.S. Cl. CPC H01L 51/0036; C08L 65/00; H01L 51/0043; C08L 2203/20; C08L 2205/025; H01L 51/4253

(57) ABSTRACT

The present application relates to a photoactive composition comprising a blend of polymers. The present application further relates to an organic photovoltaic cell or an organic photodetector comprising a photoactive layer consisting of said photoactive composition.

### TECHNICAL FIELD

The present application relates to a photoactive composition comprising a blend of polymers. The present application further relates to an organic photovoltaic cell or an organic photodetector comprising a photoactive layer consisting of said photoactive composition.

### BACKGROUND

Recently, organic photodetectors (OPDs) have started to attract attention because they offer unique advantages, such as low weight as well as good flexibility and conformability. Such organic photodetectors are useful for applications in, for example, touchless sensing, x-ray detection, and light sensing.

Organic photodetectors typically consist of a sequence of layers, which include an anode, an optional electron transport layer, a bulk heterojunction (BHJ) layer, an optional hole transport layer, and a cathode. To a significant degree the performance of an organic photodetector is determined by the BHJ layer, which serves as the photoactive layer, and will depend upon the BHJ layer's efficiency in absorbing light (i.e. photons) as well as its efficiency in charge separation. Typical preferred requirements in terms of device performance are a low dark current (preferably <10−7 A/cm²), an on/off ratio of preferably above 10³, linearity across a wide range of light intensities, and reasonable external quantum efficiency (EQE).

Generally the BHJ layer comprises a p-type semiconductor as electron donor and an n-type semiconductor as electron acceptor. The p-type semiconductor may, for example, be a low band gap polymeric semiconductor. The n-type semiconductor may, for example, be a fullerene.

The photoactive layer may be deposited using a range of coating techniques such as blanket coating (e.g. slot die coating, or knife coating) or patterned coating (e.g. screen printing, gravure, or inkjet). When using a liquid coating technique, wherein the p-type semiconductor and the n-type semiconductor are employed as a formulation, i.e. are comprised in a solvent, such formulation might need to be adapted to specific equipment and processing conditions, for example, by modifying the viscosity of the formulation so as to allow for good and reproducible deposition.

Despite significant research efforts, the preparation of a formulation for the deposition of a BHJ layer remains challenging. In part this is due to the fact that a common solvent for both, the p-type semiconductor and the n-type semiconductor, needs to be found. Furthermore, the physical properties of the formulation, particularly the viscosity, need to be adapted to the respective liquid deposition technique.

Current methods for modifying the viscosity of the formulation focus on changing concentration, molecular weight, and/or solubility of the polymeric p-type semiconductor. However, in many instances such methods have been found unsuitable and/or may even lead to significant disadvantages. For instance, an increase in molecular weight generally also leads to reduced solubility, thereby potentially offsetting the intended effect either partially or even completely. In other instances it may, for example, not be feasible to produce a polymer having a higher molecular weight. Or the increase in molecular weight of the polymeric p-type semiconductor might for reasons of solubility require the use of undesirable solvents.

Hence, it is an aim of the present application to overcome one or more of the aforementioned problems of the art. It is also an aim of the present application to allow providing a photoactive formulation having good and/or easily adaptable processability, preferably while essentially maintaining or possibly even improving device performance. Additionally, it is an aim of the present application to provide for a simple method of allowing to change the viscosity of a photoactive formulation, which would allow easy adaptation to different processing equipment and different deposition processes. Furthermore, it is an aim to provide an organic photodetector overcoming one or more of the aforementioned problems of the art without compromising device performance. Further aims of the present application directly become evident from the following description.

### SUMMARY

The present inventors have now surprisingly found that the above objects may be attained either individually or in any combination by the present products and processes.

Thus, the present application provides for a photoactive composition comprising an electron donor and an electron acceptor, with the electron donor comprising at least a first organic semiconducting polymer and at least a second organic semiconducting polymer that is different from the first organic semiconducting polymer, wherein the first organic semiconducting polymer and the second organic semiconducting polymer have a difference in band gap (ΔE_{g}) of at least 0.20 eV, with band gaps determined by optical absorption

The present application further provides for a photoactive formulation comprising such photoactive composition and an organic solvent.

Furthermore, the present application provides for an organic photovoltaic cell or an organic photodetector comprising a photoactive layer consisting of such photoactive composition.

Additionally, the present application provides for a process for producing such an organic photovoltaic cell or organic photodetector, said process comprising the steps of
(a) providing a first electrode on a substrate;
(b) optionally forming an electron transport layer (ETL) on the electrode;
(c) subsequently depositing said photoactive formulation on the electrode and removing the organic solvent, thereby obtaining a photoactive layer consisting of said photoactive composition;
(d) optionally forming a hole transporting layer (HTL) on the photoactive layer; and
(e) subsequently forming the second electrode.

### BRIEF DESCRIPTION OF THE DRAWINGS

FIG. 1 shows the viscosity of the exemplary photoactive formulations of Example 1 as a function of shear rate.

FIG. 2 shows the IV-curves, determined between −5 V and 2 V under dark and light conditions, of the exemplary organic photodetector devices of Example 1.

FIG. 3 shows the viscosity of the exemplary photoactive formulations of Example 2 as a function of shear rate.

FIG. 4 shows the IV-curves, determined between −5 V and 2 V under dark and light conditions, of the exemplary organic photodetector devices of Example 2.

### DETAILED DESCRIPTION

As used herein the term “polymer” generally also includes homopolymers and copolymers, such as block copolymers and random copolymers.

As used herein, the expressions “semiconducting polymer(s)” and “polymeric semiconductor(s)” are used synonymously.

As used herein, the singular forms “a”, “an”, and “the” include both singular and plural referents unless the context clearly dictates otherwise.

The terms “comprising”, “comprises” and “comprised of” as used herein are synonymous with “including”, “includes” or “containing”, “contains”, and are inclusive or open-ended and do not exclude additional, non-recited members, elements or method steps. It will be appreciated that the terms “comprising”, “comprises” and “comprised of” as used herein comprise the terms “consisting of”, “consists” and “consists of”.

The recitation of numerical ranges by endpoints includes all numbers and fractions subsumed within the respective ranges, as well as the recited endpoints. Whereas the terms “one or more” or “at least one”, such as one or more or at least one member(s) of a group of members, is clear per se, by means of further exemplification, the term encompasses inter alia a reference to any one of said members, or to any two or more of said members, such as, e.g., any 3, 4, 5, 6 or 7 etc. of said members, and up to all said members.

All references cited in the present specification are hereby incorporated by reference in their entirety. In particular, the teachings of all references herein specifically referred to are incorporated by reference.

Unless otherwise defined, all terms used in disclosing the application, including technical and scientific terms, have the meaning as commonly understood by one of ordinary skill in the art to which this application belongs. By means of further guidance, definitions of terms and expressions are included to better appreciate the teaching of the present application.

In the following passages, different aspects of the application are defined in more detail. Each aspect so defined may be combined with any other aspect or aspects unless clearly indicated to the contrary. In particular, any feature indicated as being preferred or advantageous may be combined with any other feature or features indicated as being preferred or advantageous.

Reference throughout this specification to “one embodiment” or “an embodiment” means that a particular feature, structure or characteristic described in connection with the embodiment is included in at least one embodiment of the present application. Thus, appearances of the phrases “in one embodiment” or “in an embodiment” in various places throughout this specification are not necessarily all referring to the same embodiment, but may. Furthermore, the particular features, structures or characteristics may be combined in any suitable manner, as would be apparent to a person skilled in the art from this disclosure, in one or more embodiments. Furthermore, while some embodiments described herein include some but not other features included in other embodiments, combinations of features of different embodiments are meant to be within the scope of the application, and form different embodiments, as would be understood by those in the art. For example, in the appended claims, any of the claimed embodiments can be used in any combination.

### Composition

In general terms the present application relates to a photoactive composition comprising an electron donor and an electron acceptor, with the electron donor comprising at least a first organic semiconducting polymer, in the following referred to as “first polymer”, and at least a second organic semiconducting polymer, in the following referred to as “second polymer”, that is different from the first polymer, wherein the first polymer is a low band gap polymer and the second polymer is a high band gap polymer.

For the present semiconducting polymers, the term “band gap (ΔE_{g})” refers to the energy difference in potential (given in eV) between the highest occupied molecular orbital (HOMO) and the lowest unoccupied molecular orbital (LUMO), i.e. ΔE_{g}=E_{HOMO}−E_{LUMO}. For the purposes of the present application, band gaps were determined by optical absorption.

Methods for determining the band gap are disclosed, for example, by K. Seki and K. Kanai, Molecular Crystals and Liquid Crystals, Vol. 455, pages 145-181 (2006), DOI: 10.1080/15421400600803713; or by S. M. Tadayyon et al., Organic Electronics 5 (2004) 199-205, particularly page 201, “2. Experimental”; or by J. C. S. Costa, Optical Materials 58 (2016) 61-60.

The difference in band gap (ΔE_{g}) between the first polymer and the second polymer is at least 0.20 eV, preferably at least 0.30 eV, more preferably at least 0.40 eV, and most preferably at least 0.50 eV, with the difference ΔE_{g} being taken as absolute value.

Preferably, the difference in band gap (ΔE_{g}) between the first polymer and the second polymer is at most 2.00 eV, more preferably at most 1.50 eV, even more preferably at most 1.00 eV, still even more preferably at most 0.90 eV, and most preferably at most 0.80 eV, with the difference ΔE_{g} being taken as absolute value.

For the purposes of the present application the first polymer preferably has a band gap of at most 2.05 eV, more preferably of at most 2.00 eV, even more preferably of at most 1.90 eV, and most preferably of at most 1.80 eV. The first polymer preferably has a band gap of at least 0.50 eV, more preferably of at least 1.00 eV, and most preferably at least 1.50 eV.

For the purposes of the present application, the second polymer preferably has a band gap of at least 2.15 eV, preferably of at least 2.20 eV, even more preferably of at least 2.30 eV, and most preferably of at least 2.40 eV. Such high band gap material or polymer preferably has a band gap of at most 5.0 eV, more preferably of at most 4.5 eV, even more preferably of at most 4.0 eV, still even more preferably of at most 3.5 eV, and most preferably at most 3.0 eV.

Preferably, the first polymer has a weight average molecular weight M_{w} of at least 5,000 g mol⁻¹, more preferably of at least 10,000 g mol⁻¹, even more preferably of at least 15,000 g mol⁻¹, still even more preferably of at least 20,000 g mol⁻¹, and most preferably of at least 25,000 g mol⁻¹, determined by GPC as described below.

Preferably, the first polymer has a weight average molecular weight M_{w} of at most 120,000 g mol⁻¹ or 110,000 g mol⁻¹, more preferably of at most 100,000 g mol⁻¹ or 90,000 g mol⁻¹, even more preferably of at most 80,000 g mol⁻¹ or 70,000 g mol⁻¹, still even more preferably of at most 60,000 g mol⁻¹, and most preferably of at most 50,000 g mol⁻¹, determined by GPC as described below.

Preferably, the second polymer has a weight average molecular weight M_{w} of at least 130,000 g mol⁻¹ (for example, 140,000 g mol⁻¹,or 150,000 g mol⁻¹, 160,000 g mol⁻¹, or 170,000 g mol⁻¹, or 180,000 g mol⁻¹, or 190,000 g mol⁻¹), more preferably of at least 200,000 g mol⁻¹, even more preferably of at least 250,000 g mol⁻¹, and most preferably at least 300,000 g mol⁻¹, determined by GPC as described below.

Though the upper limit of the weight average molecular weight M_{w} of the second polymer is not particularly limited, it is nevertheless preferred that the M_{w} of the second polymer is at most 1,000,000 g mol⁻¹, more preferably at most 750,000 g mol⁻¹, and most preferably at most 500,000 g mol⁻¹, determined by GPC as described below.

The difference in weight average molecular weight ΔM_{w} of the average molecular weights of the first and second polymers is at least 50,000 g mol⁻¹, more preferably at least 100,000 g mol⁻¹, even more preferably at least 125,000 g mol⁻¹, still even more preferably at least 150,000 g mol⁻¹, and most preferably at least 200,000 g mol⁻¹, with the respective weight average molecular weights determined by GPC as described herein.

Molecular weights of the present polymers may be determined by gel permeation chromatography (GPC) on commercially available equipment, having two Phenomenex Phenogel Linear Column and a Phenogel 10⁶ Å Column (all columns are 10 μm packed capillary columns) and a refractive index detector, for example, in dichlorobenzene at 50° C. using commercially available narrow molecular weight standards of polystyrene for calibration.

The weight ratio of the first polymer to the second polymer is preferably at least 1:1 to at most 10:1; more preferably at least 1:1 to at most 5:1; even more preferably at least 1:1 to at most 3:1.; and most preferably at least 1:1 to at most 2:1.

The weight ratio of electron donor to electron acceptor is preferably at least 2:1, more preferably at least 1.5:1, even more preferably at least 1:1.

The weight ratio of electron donor to electron acceptor preferably is at most 1:10, more preferably at most 1:9 or 1:8 or 1:7 or 1:6, even more preferably at most 1:5 or 1:4 or 1:3, and most preferably at most 1:2.

Present first polymer and second polymer may be represented by the following formula (I)

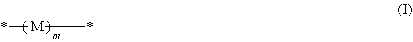

wherein monomeric unit M and m are as defined herein. At each occurrence M may be selected independently.

For the purposes of the present application, except where otherwise specifically defined differently, an asterisk “*” is used to denote a linkage to an adjacent unit or group, including for example, in case of a polymer, to an adjacent repeating unit or any other group. In some instances, where specifically identified as such, the asterisk “*” may also denote a mono-valent chemical group.

With regards to formula (I) m may be any integer from 1 to 100,000. For a monomer or monomeric unit m is 1. Preferably, m is selected such that the respective polymer has the above-defined weight average molecular weight M. As used herein, for an oligomer m is at least 2 and at most 10. As used herein, for a polymer m is at least 11.

Preferably, the first polymer and the second polymer, independently of each other, comprise one or more aromatic units. Expressed differently, with regards to formula (I), M may comprise one or more aromatic unit. Suitable aromatic units preferably comprise two or more, or even three or more aromatic rings. Such aromatic rings may, for example, at each occurrence independently be selected from the group consisting of 5-, 6-, 7- and 8-membered aromatic rings, with 5- and 6-membered rings being particularly preferred.

These aromatic rings comprised in the first and second polymer optionally comprise one or more heteroatoms selected from Se, Te, P, Si, B, As, N, O or S, preferably from Si, N, O or S. Further, these aromatic rings may optionally be substituted with alkyl, alkoxy, polyalkoxy, thioalkyl, acyl, aryl or substituted aryl groups, halogen, with fluorine being the preferred halogen, cyano, nitro or an optionally substituted secondary or tertiary alkylamine or arylamine represented by —N(R′)(R″), where R′ and R″ are each independently H, an optionally substituted alkyl or an optionally substituted aryl, alkoxy or polyalkoxy groups are typically employed. Further, where R′ and R″ is alkyl or aryl these may be optionally fluorinated.

The aforementioned aromatic rings can be fused rings or linked to each other by a conjugated linking group such as —C(T₁)═C(T₂)—, —C≡C—, —N(R′″)—, —N═N—, (R′″)═N—, —N═C(R′″)—, where T₁ and T₂ each independently represent H, Cl, F, —C≡N or lower alkyl groups such as C₁₋₄ alkyl groups; R′″ represents H, optionally substituted alkyl or optionally substituted aryl. Further, where R′″ is alkyl or aryl, it may be optionally fluorinated.

For example, the present first and second polymers may at each occurrence independently be any polymers, such as homopolymers or copolymers, wherein the monomeric units M of formula (I) may at each occurrence be independently selected from the group consisting of the following formulae (A1) to (A86) and (D1) to (D142).

Preferably, the present first and second polymer may at each occurrence independently be a, preferably conjugated, polymer, such as a homopolymer or copolymer, comprising one or more acceptor unit at each occurrence independently selected from the group consisting of the following formulae (A1) to (A86) and one or more donor unit at each occurrence independently selected from the group consisting of the following formulae (D1) to (D142).

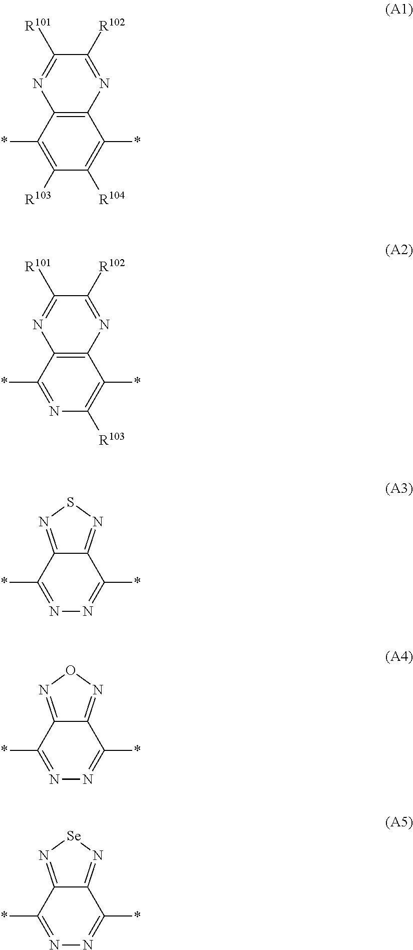

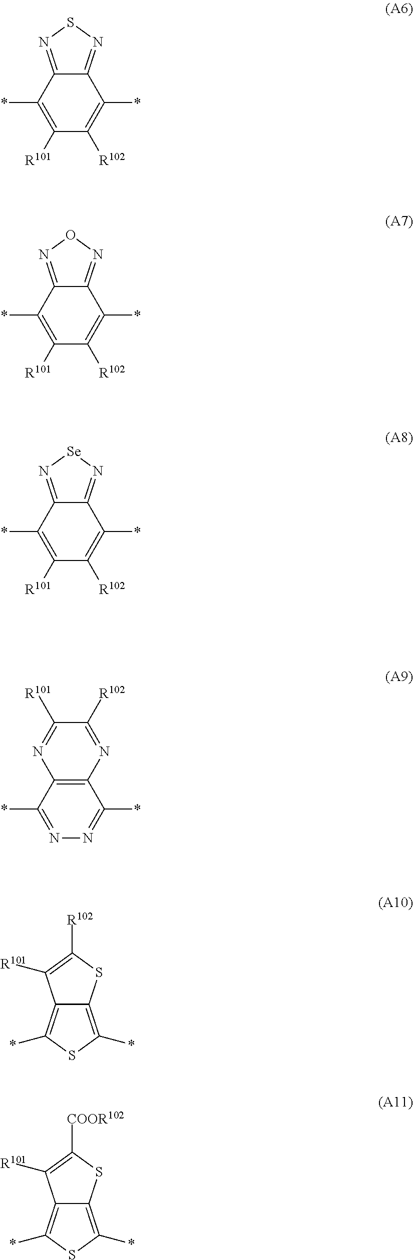

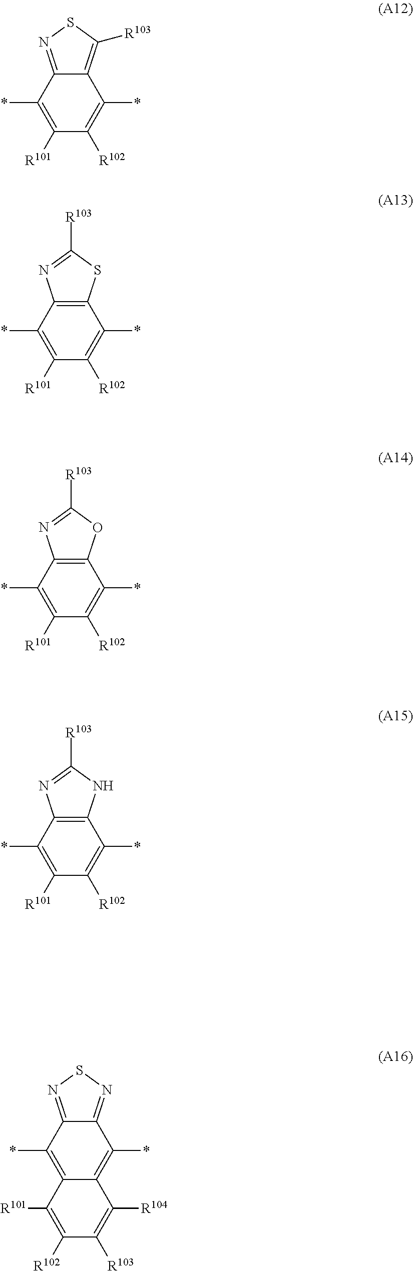

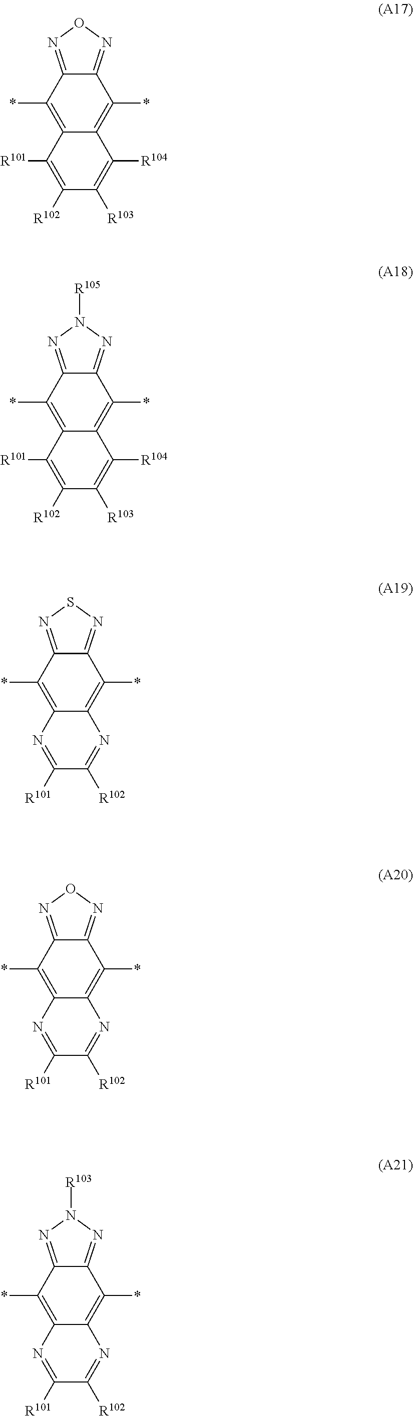

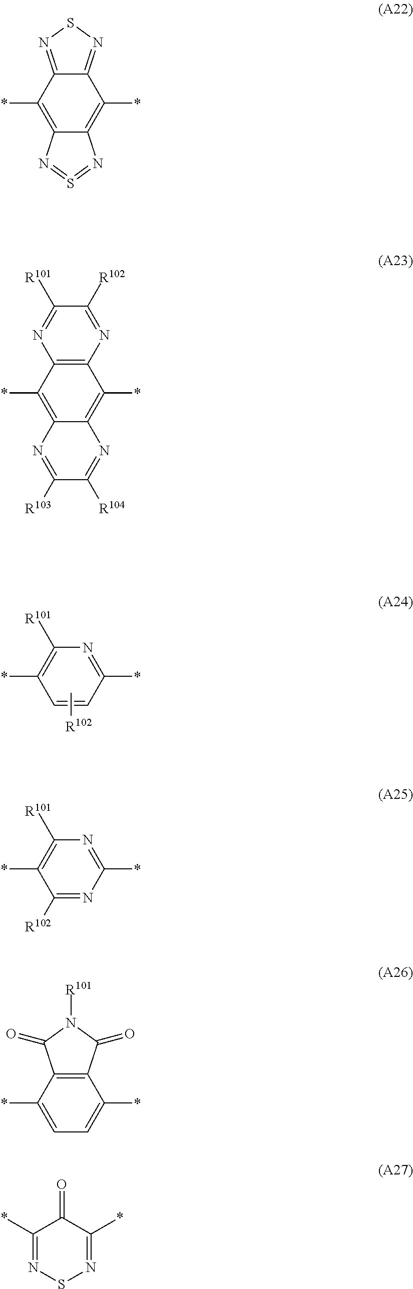

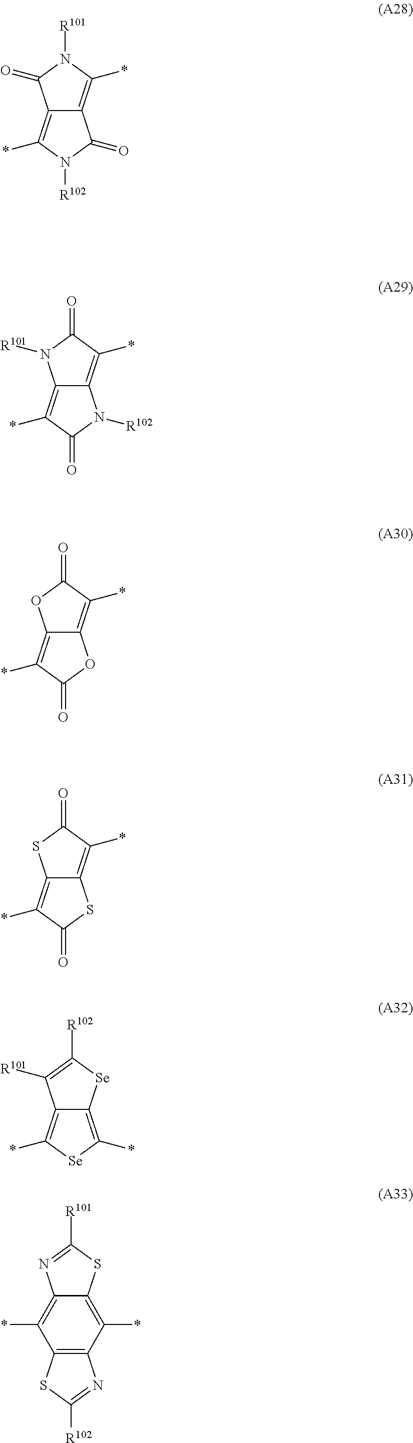

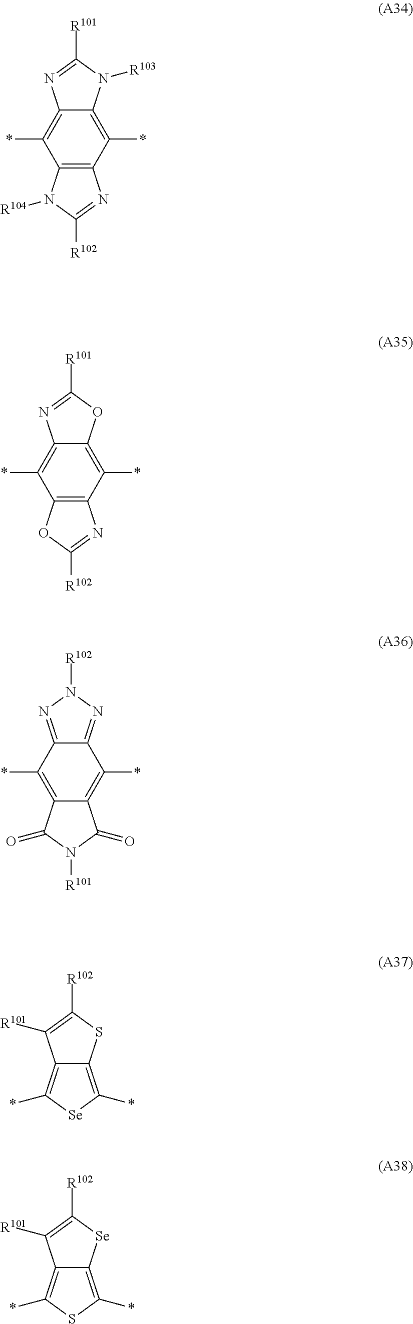

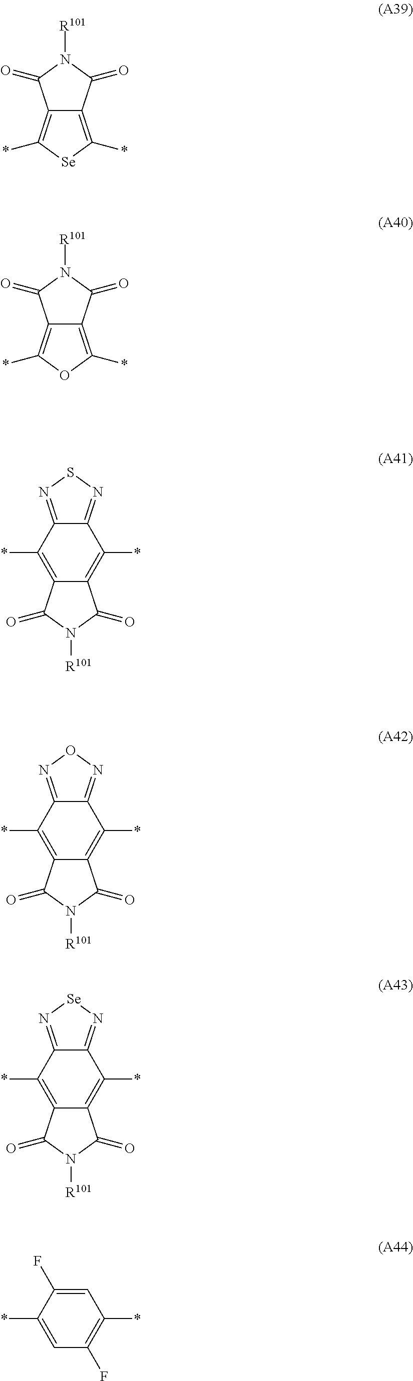

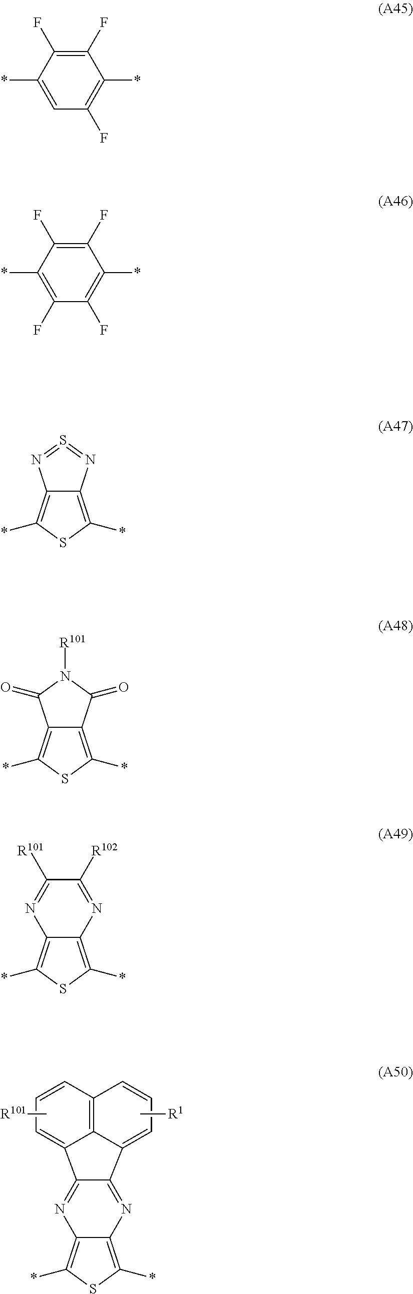

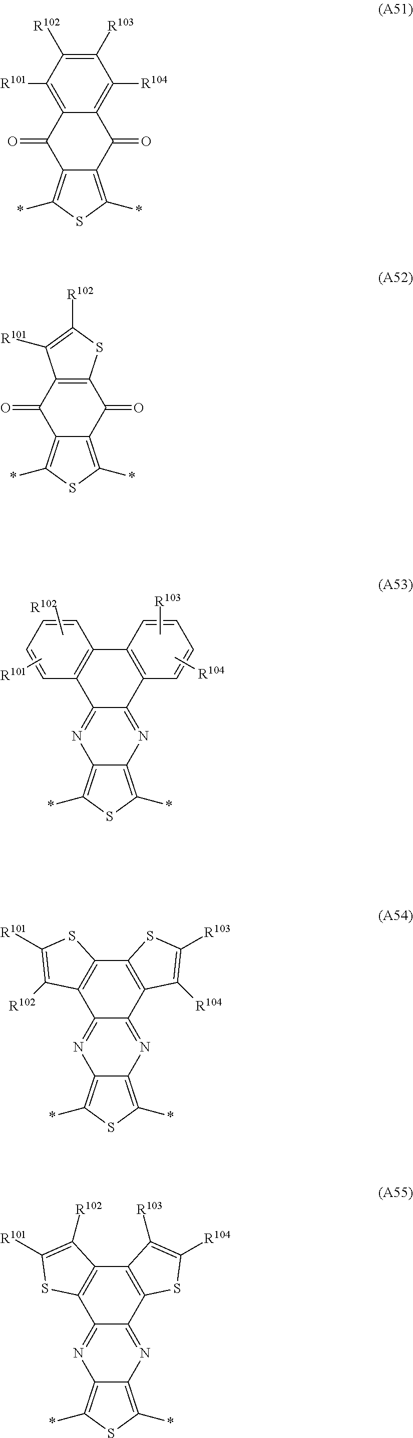

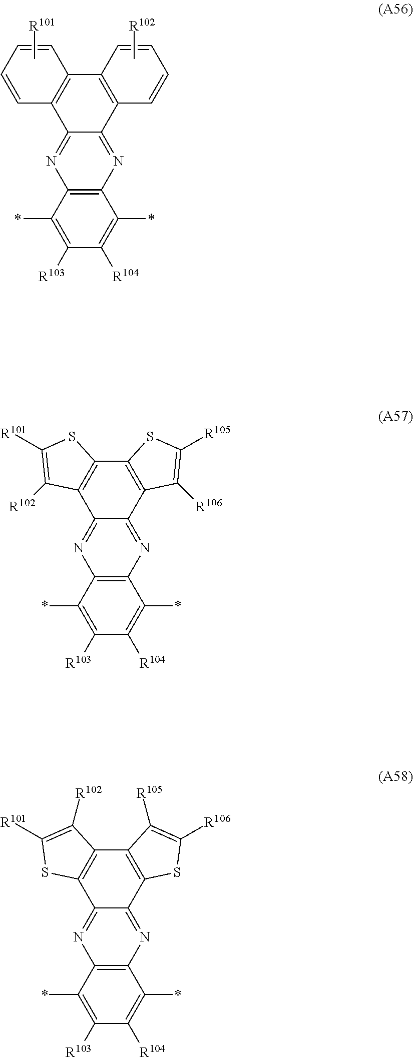

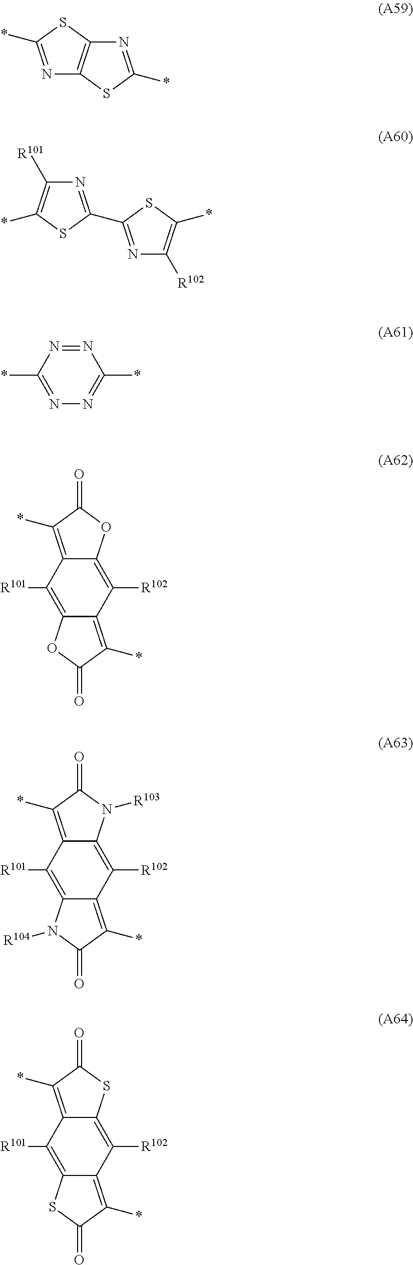

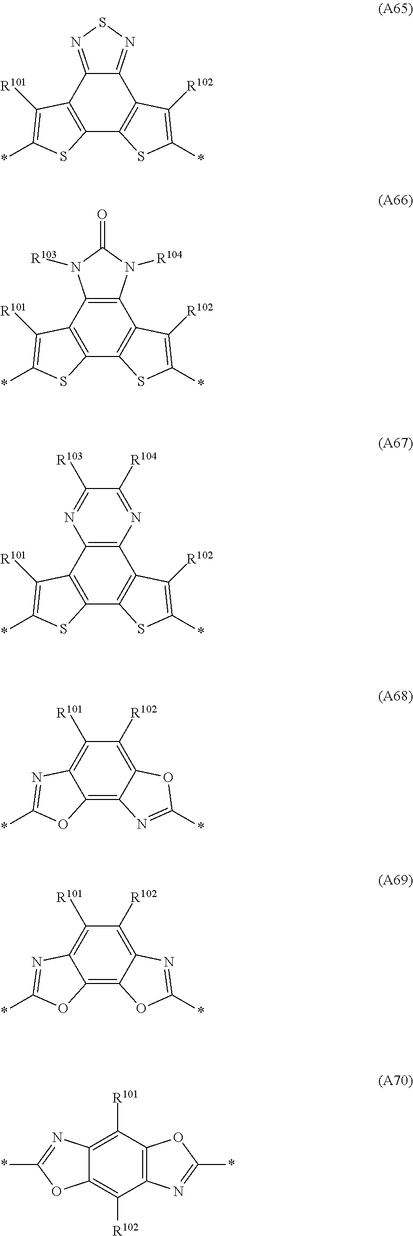

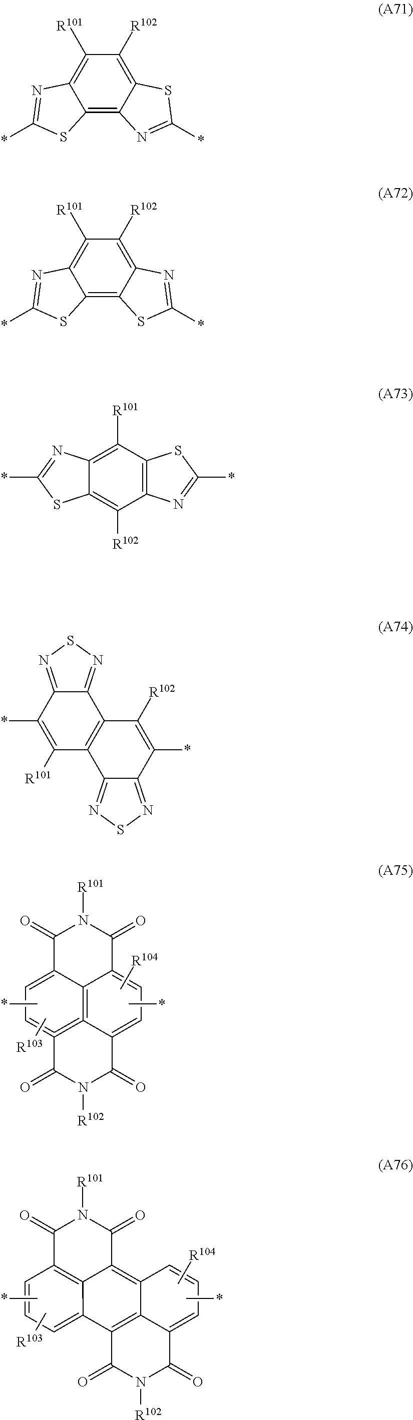

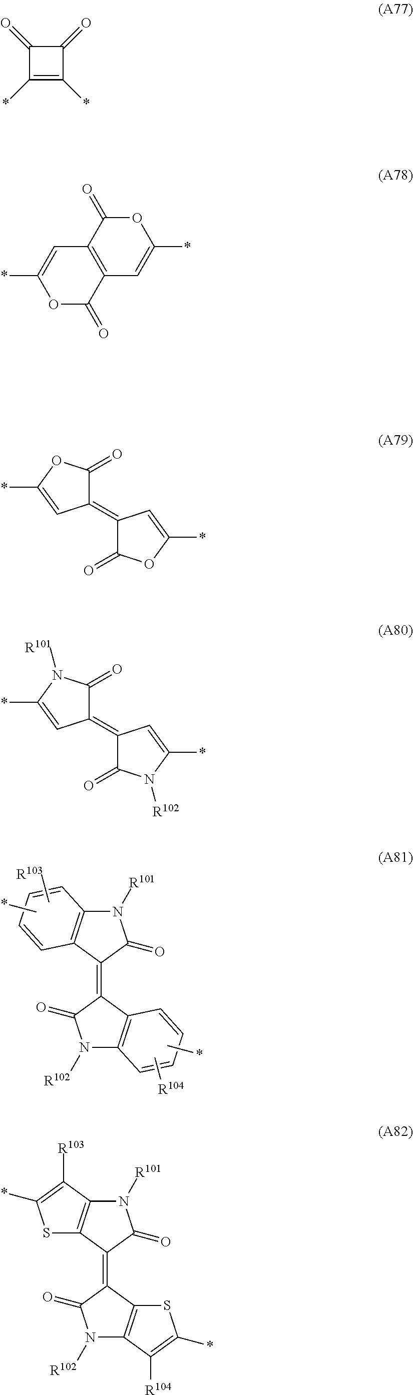

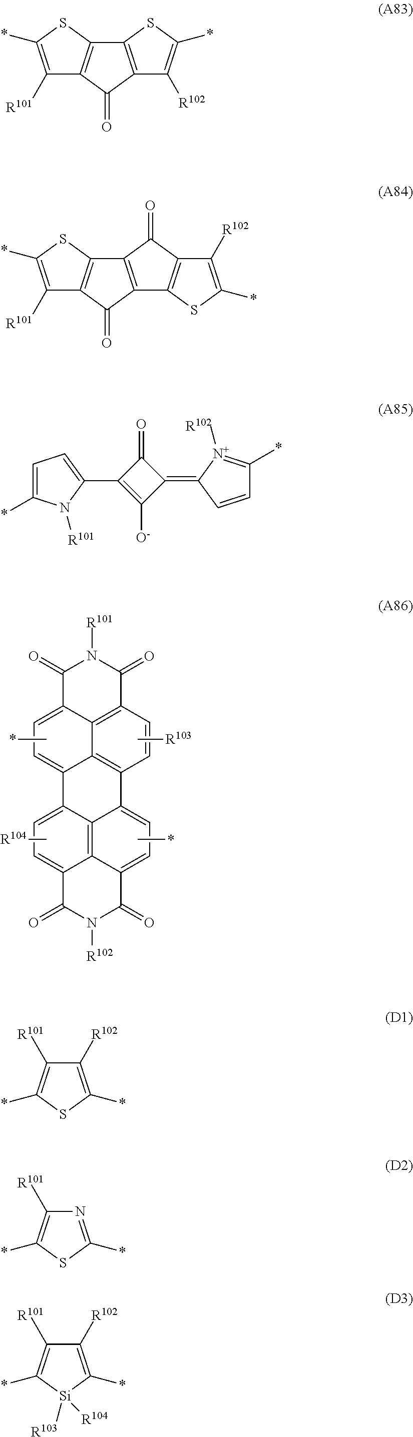

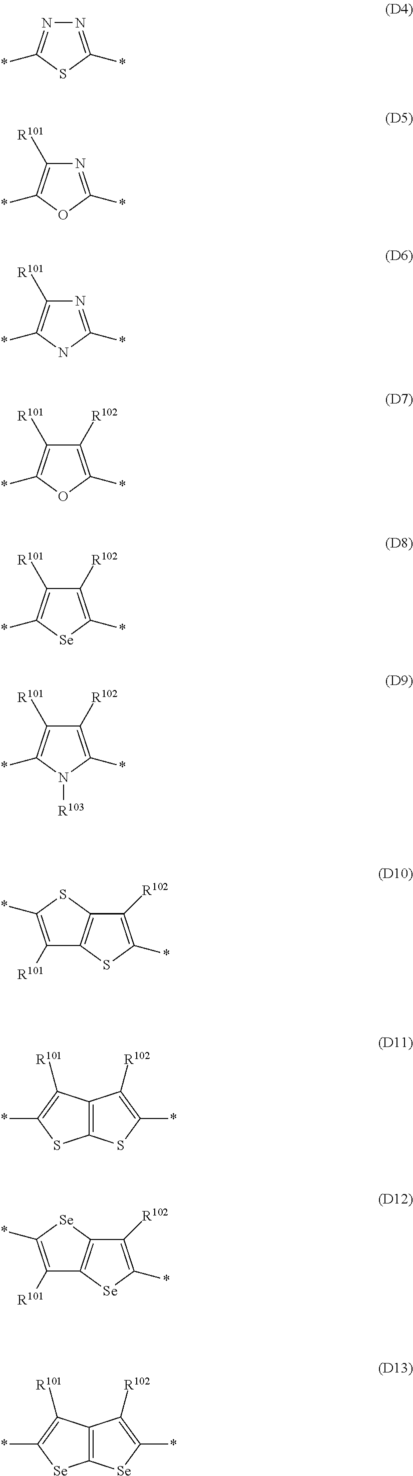

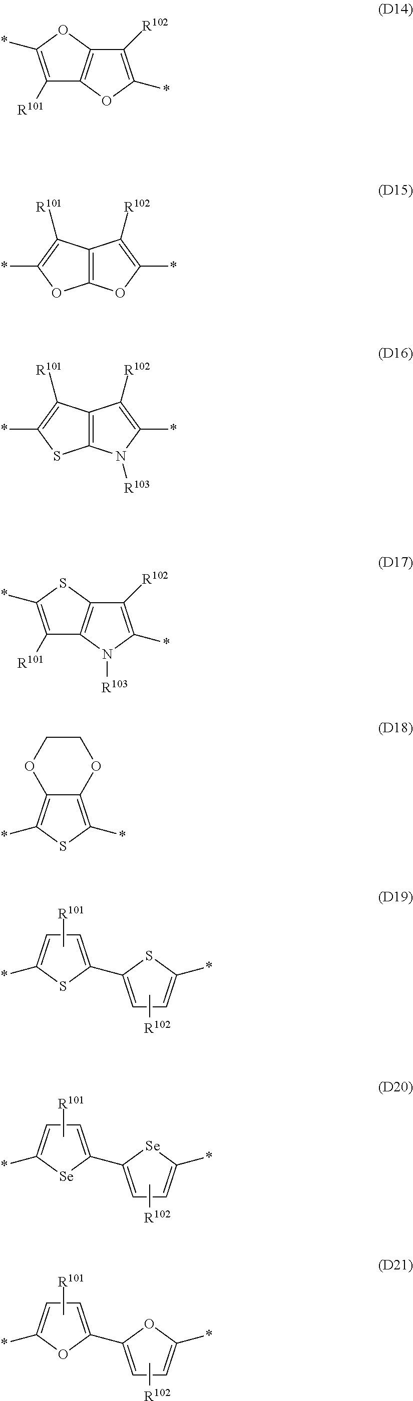

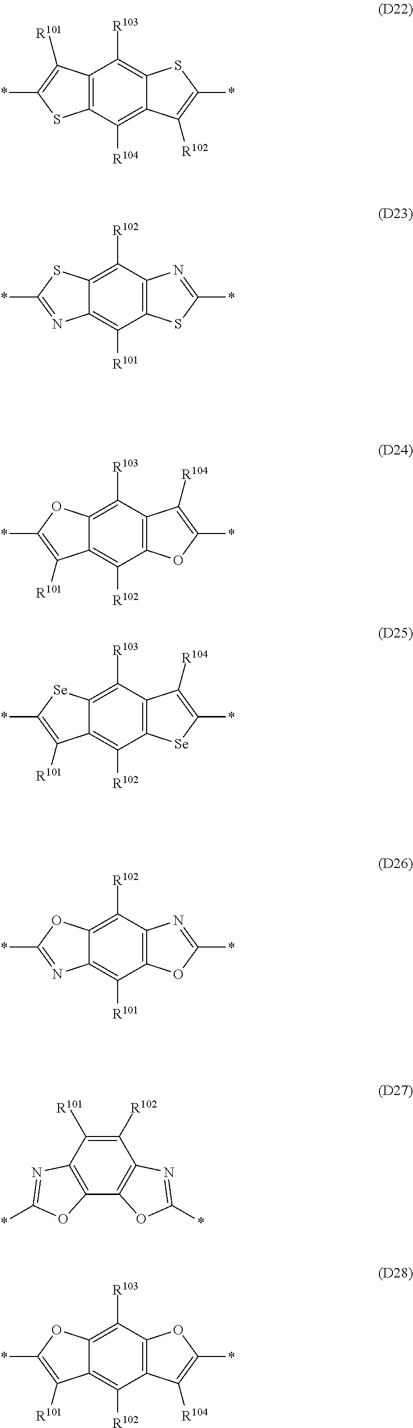

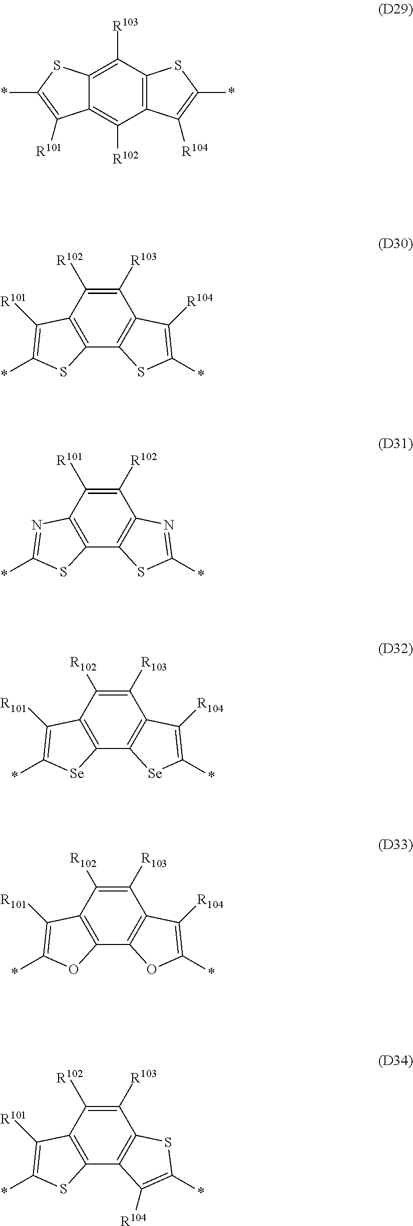

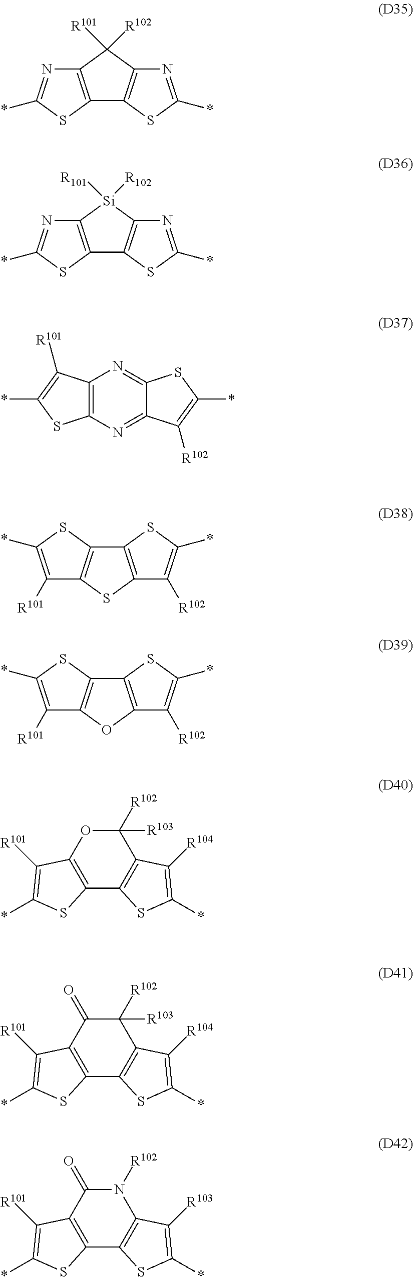

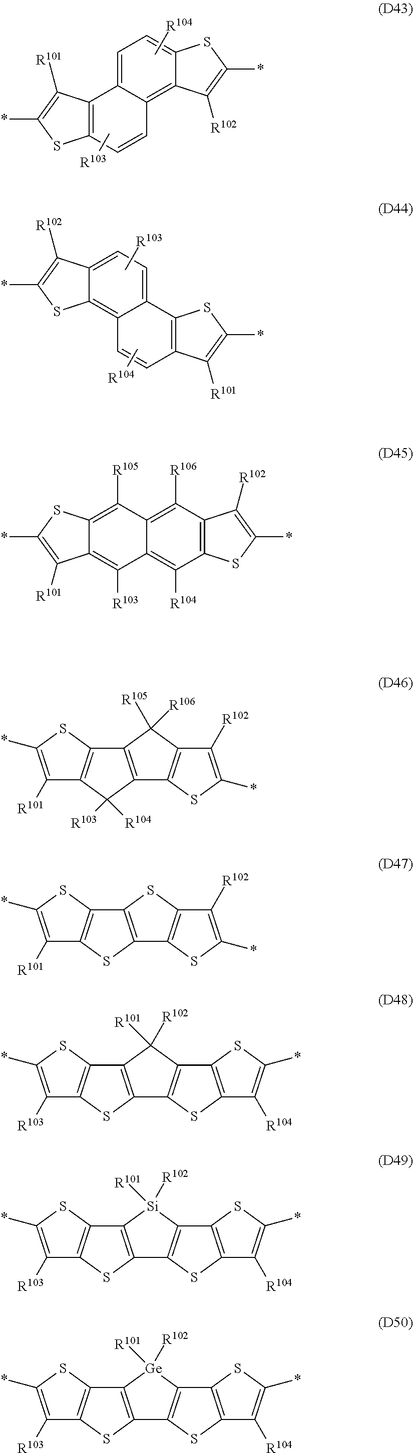

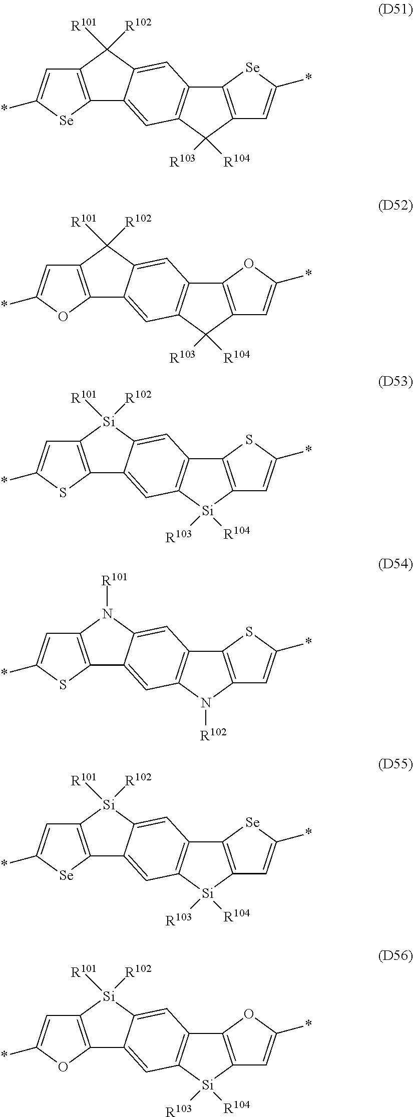

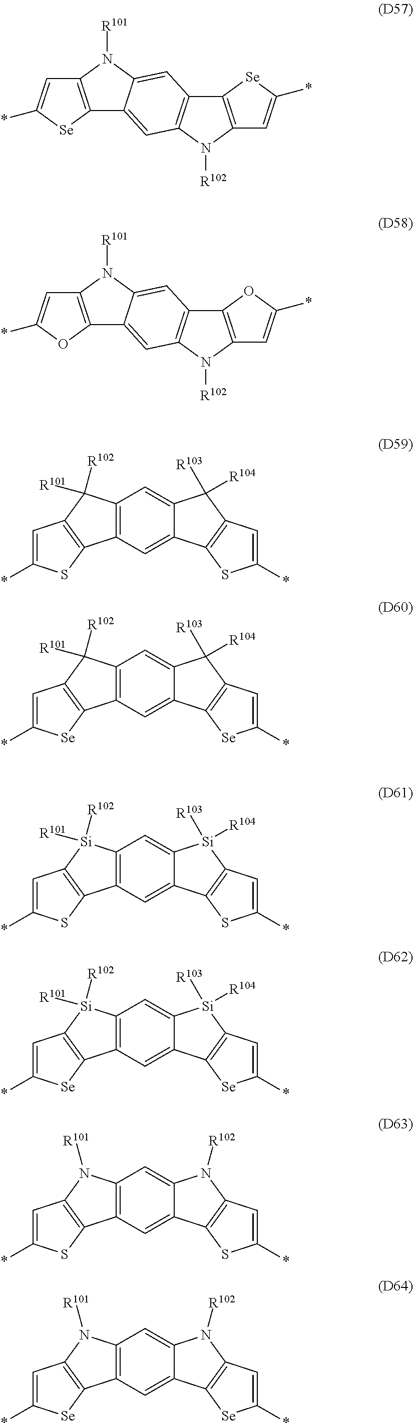

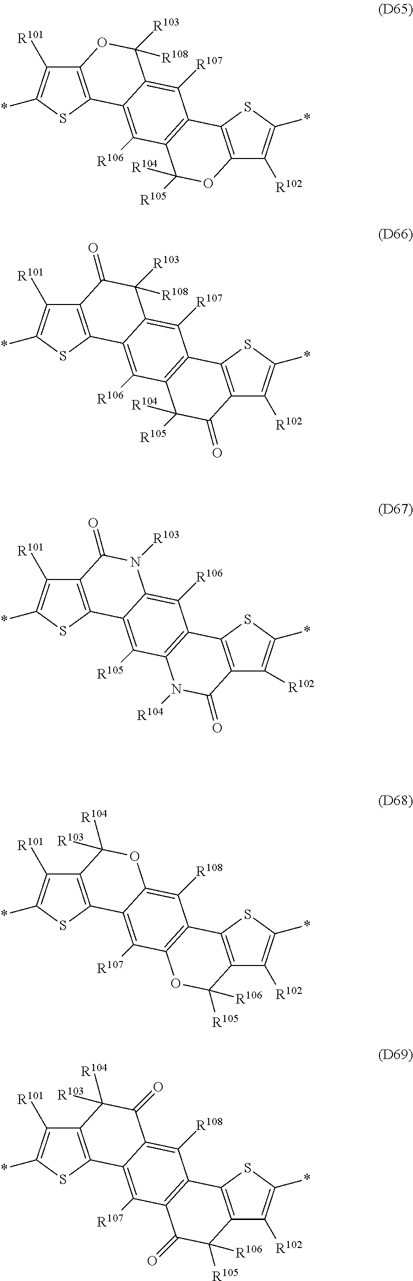

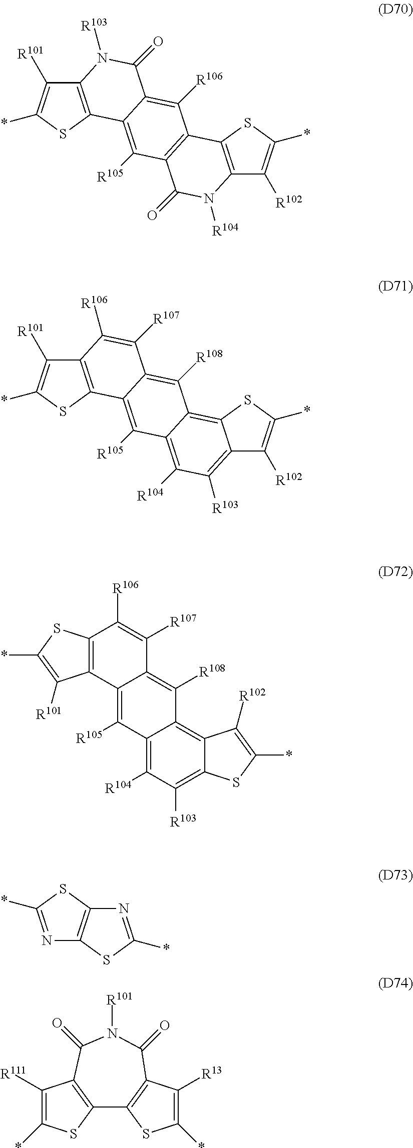

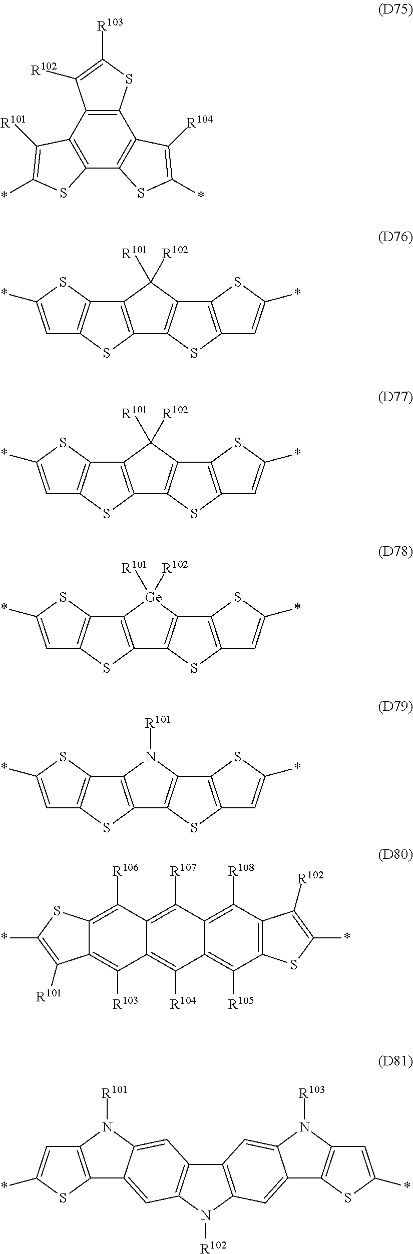

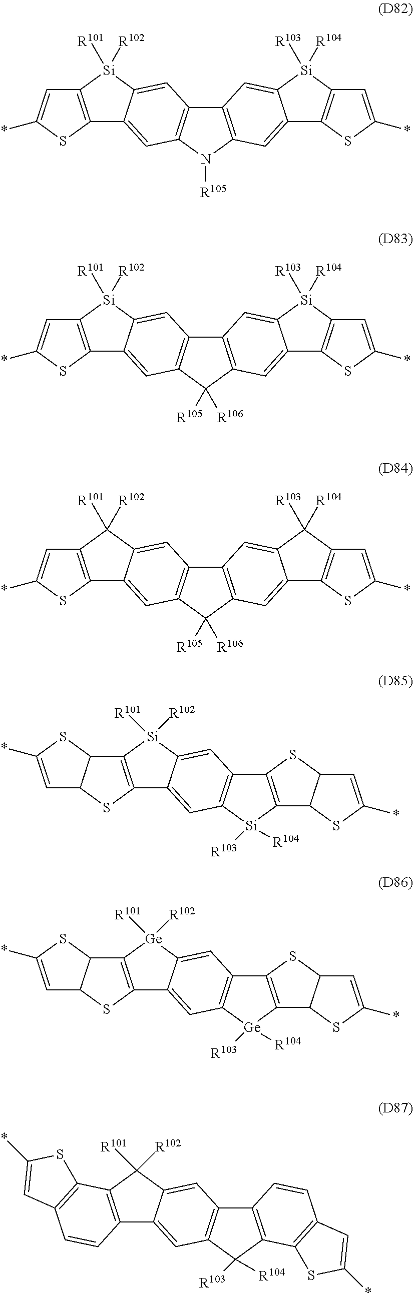

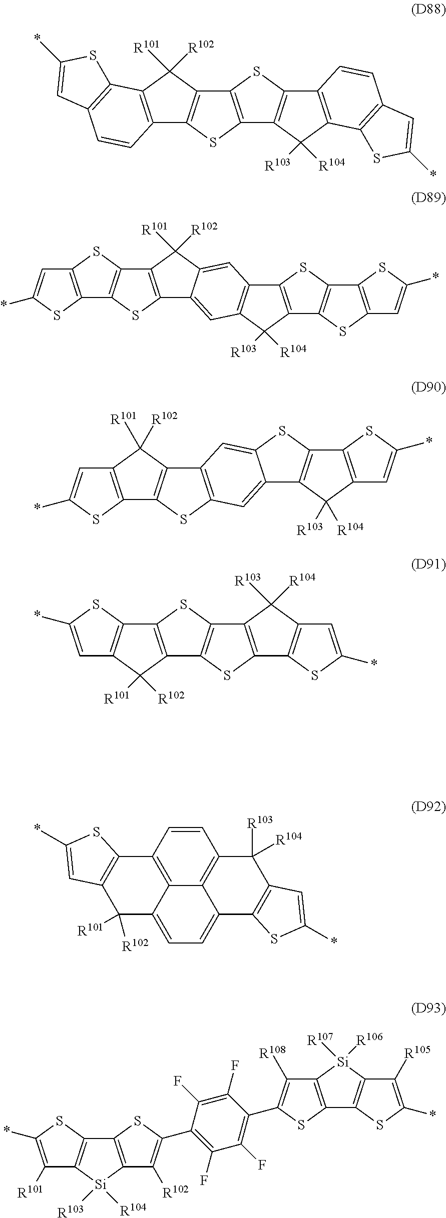

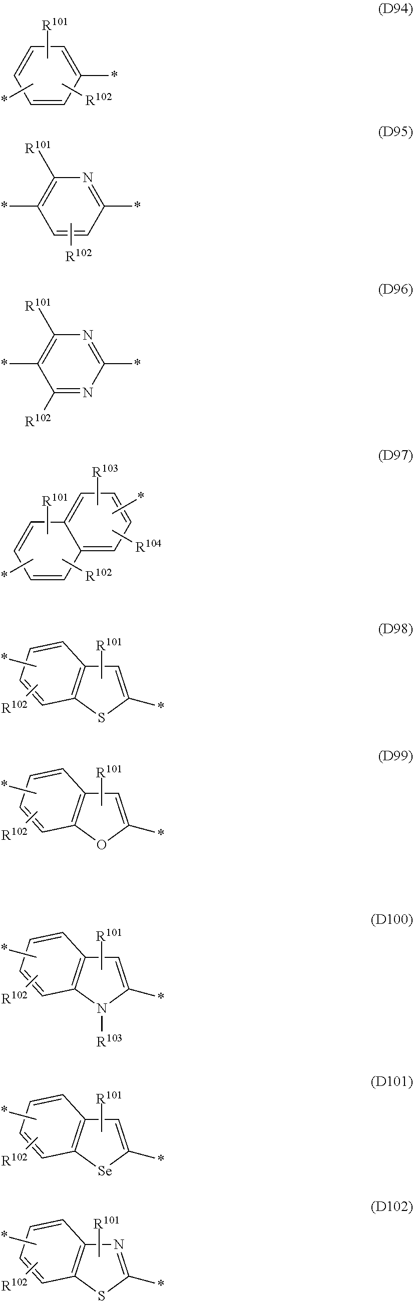

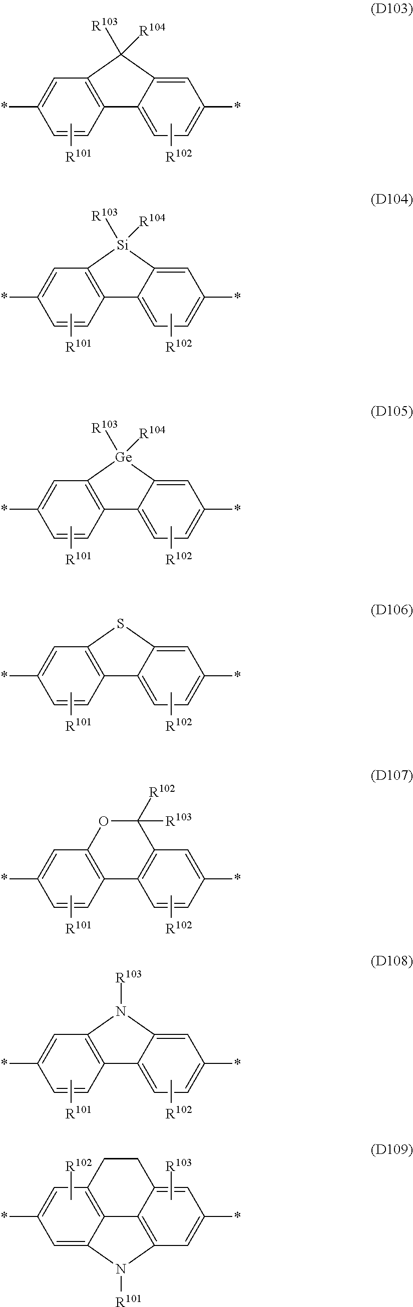

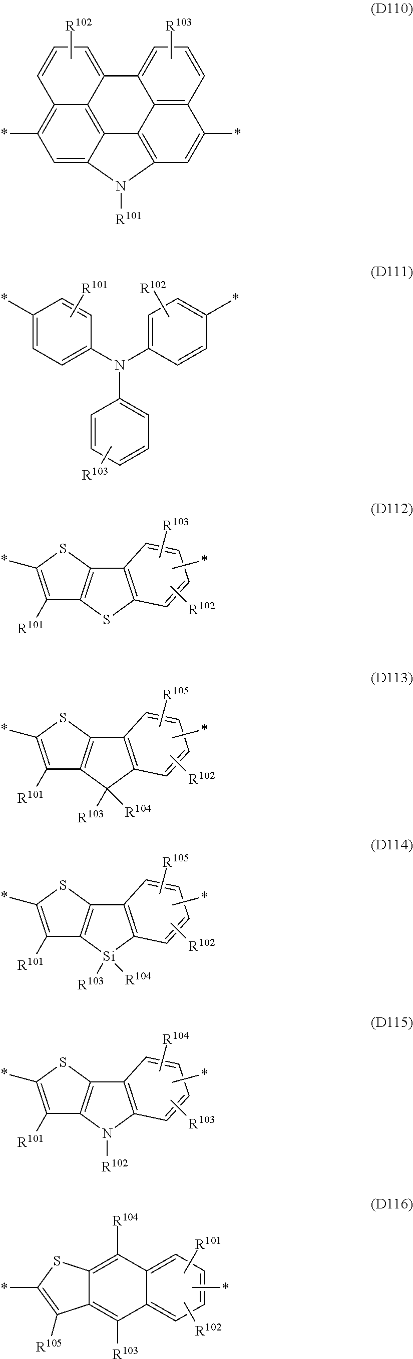

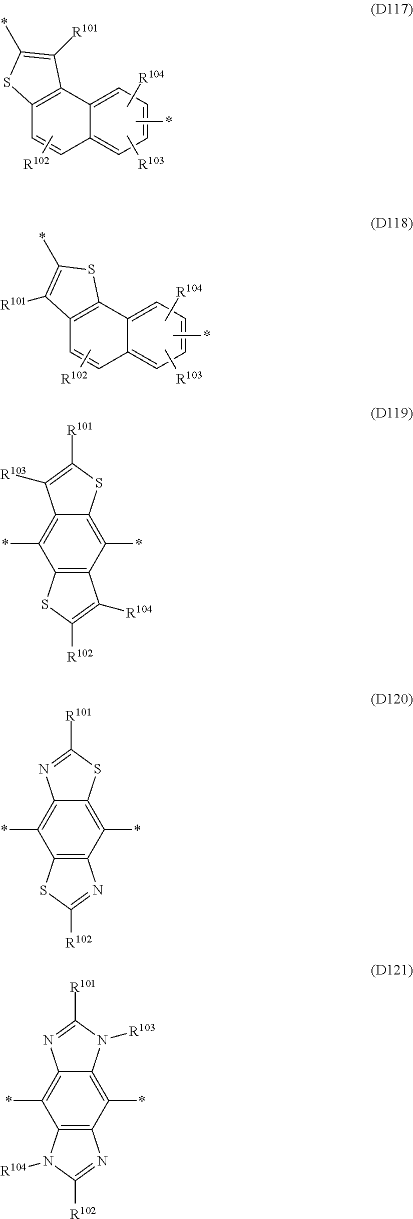

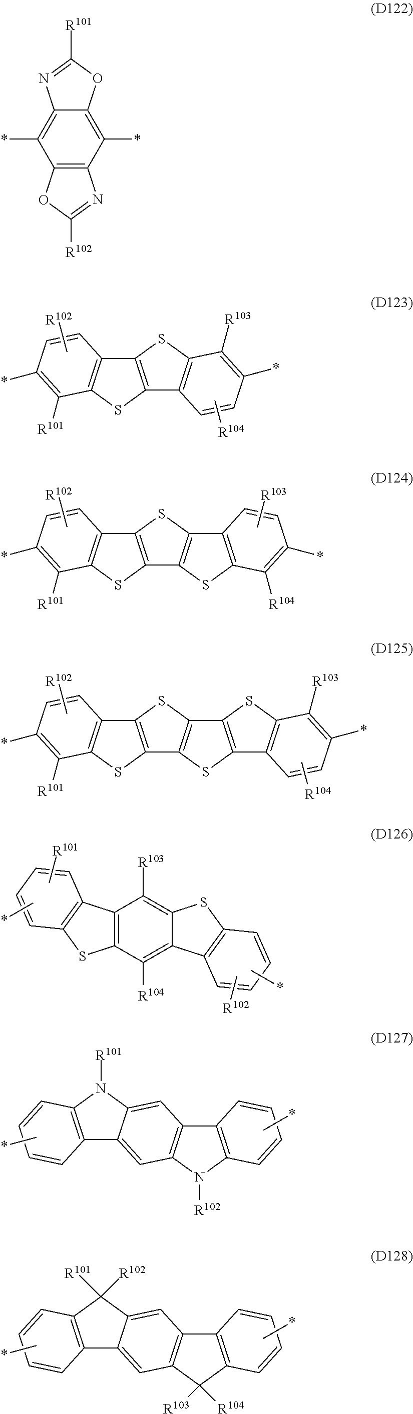

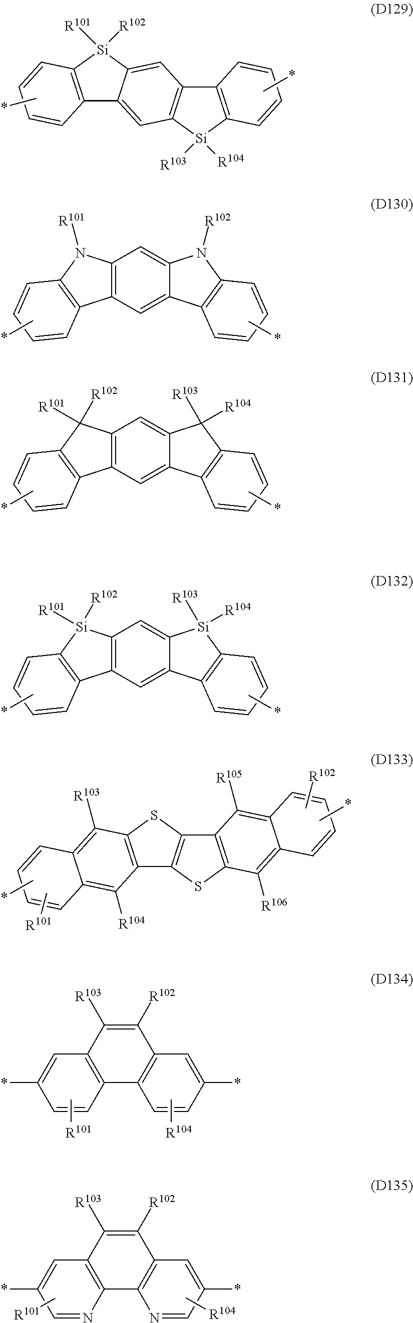

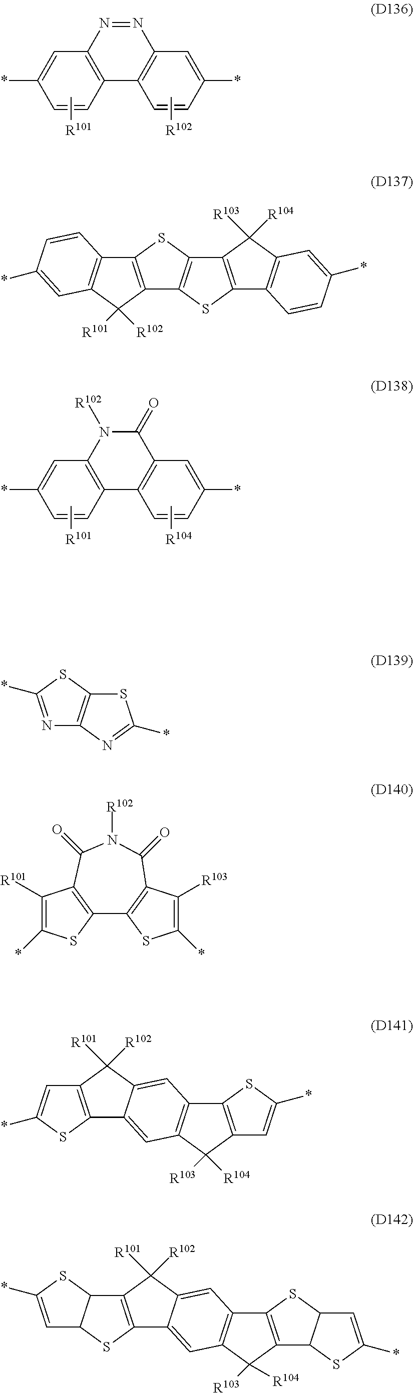

wherein R¹⁰¹, R¹⁰², R¹⁰³, R¹⁰⁴, R¹⁰⁵, R¹⁰⁶, R¹⁰⁷ and R¹⁰⁸ are independently of each other selected from the group consisting of H and R^{S} as defined herein.

R^{S} is at each occurrence independently a carbyl group as defined herein and preferably selected from the group consisting of any group R^{T} as defined herein, hydrocarbyl having from 1 to 40 carbon atoms wherein the hydrocarbyl may be further substituted with one or more groups R^{T}, and hydrocarbyl having from 1 to 40 carbon atoms comprising one or more heteroatoms selected from the group consisting of N, O, S, P, Si, Se, As, Te or Ge, with N, O and S being preferred heteroatoms, wherein the hydrocarbyl may be further substituted with one or more groups R^{T}.

Preferred examples of hydrocarbyl suitable as R^{S} may at each occurrence be independently selected from phenyl, phenyl substituted with one or more groups R^{T}, alkyl and alkyl substituted with one or more groups R^{T}, wherein the alkyl has at least 1, preferably at least 5 and has at most 40, more preferably at most 30 or 25 or 20, even more preferably at most 15 and most preferably at most 12 carbon atoms. It is noted that for example alkyl suitable as R^{S} also includes fluorinated alkyl, i.e. alkyl wherein one or more hydrogen is replaced by fluorine, and perfluorinated alkyl, i.e. alkyl wherein all of the hydrogen are replaced by fluorine.

R^{T} is at each occurrence independently selected from the group consisting of F, Br, Cl, —CN, —NC, —NCO, —NCS, —OCN, —SCN, —C(O)NR⁰R⁰⁰, —C(O)R⁰, —C(O)R⁰, —NH₂, —NR⁰R⁰⁰, —SH, —SR⁰, —SO₃H, —SO₂R⁰, —OH, —OR⁰, —NO₂, —SF_{S} and —SiR⁰R⁰⁰R⁰⁰⁰. Preferred R^{T} are selected from the group consisting of F, Br, Cl, —CN, —NC, —NCO, —NCS, —OCN, —SCN, —C(O)NR⁰R⁰⁰, —C(O)X⁰, —C(O)R⁰, —NH₂, —NR⁰R⁰⁰, —SH, —SR⁰, —OH, —OR⁰ and —SiR⁰R⁰⁰R⁰⁰⁰. Most preferred R^{T} is F.

R⁰, R⁰⁰ and R⁰⁰⁰ are at each occurrence independently of each other selected from the group consisting of H, F and hydrocarbyl having from 1 to 40 carbon atoms. Said hydrocarbyl preferably has at least 5 carbon atoms. Said hydrocarbyl preferably has at most 30, more preferably at most 25 or 20, even more preferably at most 20, and most preferably at most 12 carbon atoms. Preferably, R⁰, R⁰⁰ and R⁰⁰⁰ are at each occurrence independently of each other selected from the group consisting of H, F, alkyl, fluorinated alkyl, alkenyl, alkynyl, phenyl and fluorinated phenyl. More preferably, R⁰, R⁰⁰ and R⁰⁰⁰ are at each occurrence independently of each other selected from the group consisting of H, F, alkyl, fluorinated, preferably perfluorinated, alkyl, phenyl and fluorinated, preferably perfluorinated, phenyl.

It is noted that for example alkyl suitable as R⁰, R⁰⁰ and R⁰⁰⁰ also includes perfluorinated alkyl, i.e. alkyl wherein all of the hydrogen are replaced by fluorine.

Examples of suitable alkyls may be selected from the group consisting of methyl, ethyl, n-propyl, iso-propyl, n-butyl, iso-butyl, tert-butyl (or “t-butyl”), pentyl, hexyl, heptyl, octyl, nonyl, decyl, undecyl, dodecyl, tridecyl, tetradecyl, pentadecyl, hexadecyl, heptadecyl, octadecyl, nonadecyl and eicosyl (—C₂₀H₄₁).

X⁰ is halogen. Preferably X⁰ is selected from the group consisting of F, Cl and Br.

A hydrocarbyl group comprising a chain of 3 or more carbon atoms and heteroatoms combined may be straight chain, branched and/or cyclic, including Spiro and/or fused rings.

Hydrocarbyl suitable as R^{S}, R⁰, R⁰⁰ and/or R⁰⁰⁰ may be saturated or unsaturated. Examples of saturated hydrocarbyl include alkyl. Examples of unsaturated hydrocarbyl may be selected from the group consisting of alkenyl (including acyclic and cyclic alkenyl), alkynyl, allyl, alkyldienyl, polyenyl, aryl and heteroaryl.

Preferred hydrocarbyl suitable as R^{S}, R⁰, R⁰⁰ and/or R⁰⁰⁰ include hydrocarbyl comprising one or more heteroatoms and may for example be selected from the group consisting of alkoxy, alkylcarbonyl, alkoxycarbonyl, alkylcarbonyloxy and alkoxycarbonyloxy, alkylaryloxy, arylcarbonyl, aryloxycarbonyl, arylcarbonyloxy and aryloxycarbonyloxy.

Preferred examples of aryl and heteroaryl comprise mono-, bi- or tricyclic aromatic or heteroaromatic groups that may also comprise condensed rings, which may optionally be substituted with R^{S}.

Especially preferred aryl and heteroaryl groups may be selected from the group consisting of phenyl, phenyl wherein one or more CH groups are replaced by N, naphthalene, fluorene, thiophene, pyrrole, preferably N-pyrrole, furan, pyridine, preferably 2- or 3-pyridine, pyrimidine, pyridazine, pyrazine, triazole, tetrazole, pyrazole, imidazole, isothiazole, thiazole, thiadiazole, isoxazole, oxazole, oxadiazole, thiophene, preferably 2-thiophene, selenophene, preferably 2-selenophene, thieno[3,2-b]thiophene, thieno[2,3-b]thiophene, dithienothiophene, furo[3,2-b]furan, furo[2,3-b]furan, seleno[3,2-b]selenophene, seleno[2,3-b]selenophene, thieno[3,2-b]selenophene, thieno[3,2-b]furan, indole, isoindole, benzo[b]furan, benzo[b]thiophene, benzo[1,2-b;4,5-b′]dithiophene, benzo[2,1-b;3,4-b′]dithiophene, quinole, 2- methylquinole, isoquinole, quinoxaline, quinazoline, benzotriazole, benzimidazole, benzothiazole, benzisothiazole, benzisoxazole, benzoxadiazole, benzoxazole and benzothiadiazole.

Preferred examples of an alkoxy group, i.e. a corresponding alkyl group wherein the terminal CH₂ group is replaced by —O—, can be straight-chain or branched, preferably straight-chain (or linear). Suitable examples of such alkoxy group may be selected from the group consisting of methoxy, ethoxy, propoxy, butoxy, pentoxy, hexoxy, heptoxy, octoxy, nonoxy, decoxy, undecoxy, dodecoxy, tridecoxy, tetradecoxy, pentadecoxy, hexadecoxy, heptadecoxy and octadecoxy.

Preferred examples of alkenyl, i.e. a corresponding alkyl wherein two adjacent CH₂ groups are replaced by —CH═CH— can be straight-chain or branched. It is preferably straight-chain. Said alkenyl preferably has 2 to 10 carbon atoms. Preferred examples of alkenyl may be selected from the group consisting of vinyl, prop-1-enyl, or prop-2-enyl, but-1-enyl, but-2-enyl or but-3-enyl, pent-1-enyl, pent-2-enyl, pent-3-enyl or pent-4-enyl, hex-1-enyl, hex-2-enyl, hex-3-enyl, hex-4-enyl or hex-5-enyl, hept-1-enyl, hept-2-enyl, hept-3-enyl, hept-4-enyl, hept-5-enyl or hept-6-enyl, oct-1-enyl, oct-2-enyl, oct-3-enyl, oct-4-enyl, oct-5-enyl, oct-6-enyl or oct-7-enyl, non-1-enyl, non-2-enyl, non-3-enyl, non-4-enyl, non-5-enyl, non-6-enyl, non-7-enyl, non-8-enyl, dec-1-enyl, dec-2-enyl, dec-3-enyl, dec-4-enyl, dec-5-enyl, dec-6-enyl, dec-7-enyl, dec-8-enyl and dec-9-enyl.

Especially preferred alkenyl groups are C₂-C₂-1E-alkenyl, C₄-C₇-3E-alkenyl, C₅-C₇-4-alkenyl, C₆-C₇-5-alkenyl and C₇-6-alkenyl, in particular C₂-C₇-1E-alkenyl, C₄-C₇-3E-alkenyl and C₅-C₇-4-alkenyl. Examples of particularly preferred alkenyl groups are vinyl, 1E-propenyl, 1E-butenyl, 1E-pentenyl, 1E-hexenyl, 1E-heptenyl, 3-butenyl, 3E-pentenyl, 3E-hexenyl, 3E-heptenyl, 4-pentenyl, 4Z-hexenyl, 4E-hexenyl, 4Z-heptenyl, 5-hexenyl, 6-heptenyl and the like. Alkenyl groups having up to 5 C atoms are generally preferred.

Preferred examples of oxaalkyl, i.e. a corresponding alkyl wherein one non-terminal CH₂ group is replaced by —O—, can be straight-chain or branched, preferably straight chain. Specific examples of oxaalkyl may be selected from the group consisting of 2-oxapropyl (=methoxymethyl), 2-(═ethoxymethyl) or 3-oxabutyl (═2-methoxyethyl), 2-, 3-, or 4-oxapentyl, 2-, 3-, 4-, or 5-oxahexyl, 2-, 3-, 4-, 5-, or 6-oxaheptyl, 2-, 3-, 4-, 5-, 6- or 7-oxaoctyl, 2-, 3-, 4-, 5-, 6-, 7- or 8-oxanonyl and 2-, 3-, 4-, 5-, 6-,7-, 8- or 9-oxadecyl.

Preferred examples of carbonyloxy and oxycarbonyl, i.e. a corresponding alkyl wherein one CH₂ group is replaced by —O— and one of the thereto adjacent CH₂ groups is replaced by —C(O)—, may be selected from the group consisting of acetyloxy, propionyloxy, butyryloxy, pentanoyloxy, hexanoyloxy, acetyloxymethyl, propionyloxymethyl, butyryloxymethyl, pentanoyloxymethyl, 2-acetyloxyethyl, 2-propionyloxyethyl, 2-butyryloxyethyl, 3-acetyloxypropyl, 3-propionyloxypropyl, 4-acetyloxybutyl, methoxycarbonyl, ethoxycarbonyl, propoxycarbonyl, butoxycarbonyl, pentoxycarbonyl, methoxycarbonylmethyl, ethoxy-carbonylmethyl, propoxycarbonylmethyl, butoxycarbonylmethyl, 2-(methoxycarbonyl)ethyl, 2-(ethoxycarbonyl)ethyl, 2-(propoxycarbonyl)ethyl, 3-(methoxycarbonyl)propyl, 3-(ethoxycarbonyl)propyl, and 4-(methoxycarbonyl)-butyl.

Preferred examples of thioalkyl, i.e where one CH₂ group is replaced by —S—, may be straight-chain or branched, preferably straight-chain. Suitable examples may be selected from the group consisting of thiomethyl (—SCH₃), 1-thioethyl (—SCH₂CH₃), 1-thiopropyl (—SCH₂CH₂CH₃), 1-(thiobutyl), 1-(thiopentyl), 1-(thiohexyl), 1-(thioheptyl), 1-(thiooctyl), 1-(thiononyl), 1-(thiodecyl), 1-(thioundecyl) and 1-(thiododecyl).

A fluoroalkyl group is preferably perfluoroalkyl CᵢF₂ᵢ₊₁, wherein i is an integer from 1 to 15, in particular CF₃, C₂F₅, C₃F₇, C₄F₉, C₅F₁₁, C₆F₁₃, C₇F₁₅ or C₈F₁₇, very preferably C₆F₁₃, or partially fluorinated alkyl, in particular 1,1-difluoroalkyl, all of which are straight-chain or branched.

Alkyl, alkoxy, alkenyl, oxaalkyl, thioalkyl, carbonyl and carbonyloxy groups can be achiral or chiral groups. Particularly preferred chiral groups are 2-butyl (═1-methylpropyl), 2-methylbutyl, 2-methylpentyl, 3-methylpentyl, 2-ethylhexyl, 2-propylpentyl, 2-butyloctyl, 2-hexyldecyl, 2-octyldodecyl, 7-decylnonadecyl, in particular 2-methylbutyl, 2-methylbutoxy, 2-methylpentoxy, 3-methylpentoxy, 2-ethyl-hexoxy, 1-methylhexoxy, 2-octyloxy, 2-oxa-3-methylbutyl, 3-oxa-4-methyl-pentyl, 4-methylhexyl, 2-butyloctyl, 2-hexyldecyl, 2-octyldodecyl, 7-decylnonadecyl, 3,8-dimethyloctyl, 2-hexyl, 2-octyl, 2-nonyl, 2-decyl, 2-dodecyl, 6-meth-oxyoctoxy, 6-methyloctoxy, 6-methyloctanoyloxy, 5-methylheptyloxy-carbonyl, 2-methylbutyryloxy, 3-methylvaleroyloxy, 4-methylhexanoyloxy, 2-chloropropionyloxy, 2-chloro-3-methylbutyryloxy, 2-chloro-4-methyl-valeryl-oxy, 2-chloro-3-methylvaleryloxy, 2-methyl-3-oxapentyl, 2-methyl-3-oxa-hexyl, 1-methoxypropyl-2-oxy, 1-ethoxypropyl-2-oxy, 1-propoxypropyl-2-oxy, 1-butoxypropyl-2-oxy, 2-fluorooctyloxy, 2-fluorodecyloxy, 1,1,1-trifluoro-2-octyloxy, 1,1,1-trifluoro-2-octyl, 2-fluoromethyloctyloxy for example. Most preferred is 2-ethylhexyl.

Preferred achiral branched groups are isopropyl, isobutyl (═methylpropyl), isopentyl (=3-methylbutyl), tert. butyl, isopropoxy, 2-methyl-propoxy and 3-methylbutoxy.

In a preferred embodiment, the organyl groups are independently of each other selected from primary, secondary or tertiary alkyl or alkoxy with 1 to 30 C atoms, wherein one or more H atoms are optionally replaced by F, or aryl, aryloxy, heteroaryl or heteroaryloxy that is optionally alkylated or alkoxylated and has 4 to 30 ring atoms. Very preferred groups of this type are selected from the group consisting of the following formulae

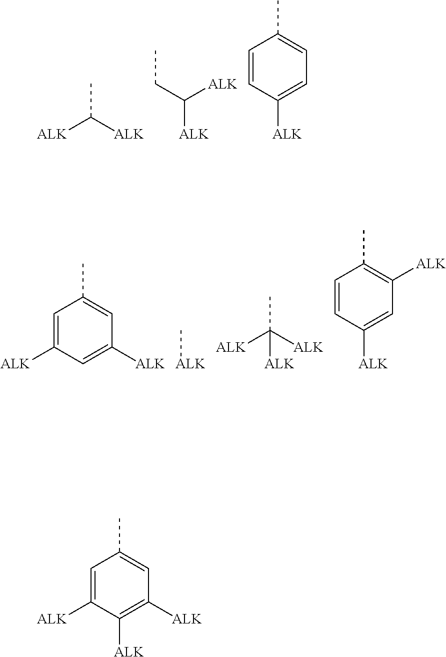

wherein “ALK” denotes optionally fluorinated, preferably linear, alkyl or alkoxy with 1 to 20, preferably 1 to 12 C-atoms, in case of tertiary groups very preferably 1 to 9 C atoms, and the dashed line denotes the link to the ring to which these groups are attached. Especially preferred among these groups are those wherein all ALK subgroups are identical.

Preferred examples of first and second polymer comprise independently of each other monomeric units M of formula (I) selected from the group consisting of formulae (A1) to (A86) and one or more monomeric units selected from the group consisting of formulae (D1) to (D142). Particularly preferred examples of suitable polymers of formula (I) comprise or preferably consist of monomeric units M that are at each occurrence independently selected from the group consisting of above formulae (A6), (D1), (D10), (D22), (D111), (D128), and (D142).

Further, in some preferred embodiments in accordance with the present invention, the present first and second polymers encompass one or more repeating units, e.g. M in formula (I), selected from thiophene-2,5-diyl, 3-substituted thiophene-2,5-diyl, optionally substituted thieno[2,3-b]thiophene-2,5-diyl, optionally substituted thieno[3,2-b]thiophene-2,5-diyl, selenophene-2,5-diyl, or 3-substituted selenophene-2,5-diyl.

Further preferred examples of first and second polymers that may be used herein include conjugated hydrocarbon polymers such as polyacene, polyphenylene, poly(phenylene vinylene), polyfluorene including oligomers of those conjugated hydrocarbon polymers; condensed aromatic hydrocarbons, such as, tetracene, chrysene, pentacene, pyrene, perylene, coronene, or soluble, substituted derivatives of these; oligomeric para substituted phenylenes such as p-quaterphenyl (p-4P), p-quinquephenyl (p-5P), p-sexiphenyl (p-6P), or soluble substituted derivatives of these; conjugated heterocyclic polymers such as poly(3-substituted thiophene), poly(3,4-bisubstituted thiophene), optionally substituted polythieno[2,3-b]thiophene, optionally substituted polythieno[3,2-b]thiophene, poly(3-substituted selenophene), polybenzothiophene, polyisothianapthene, poly(N-substituted pyrrole), poly(3-substituted pyrrole), poly(3,4-bisubstituted pyrrole), polyfuran, polypyridine, poly-1,3,4-oxadiazoles, polyisothianaphthene, poly(N-substituted aniline), poly(2-substituted aniline), poly(3-substituted aniline), poly(2,3-bisubstituted aniline), polyazulene, polypyrene; pyrazoline compounds;

polyselenophene; polybenzofuran; polyindole; polypyridazine; benzidine compounds; stilbene compounds; triazines; substituted metallo- or metal-free porphines, phthalocyanines, fluorophthalocyanines, naphthalocyanines or fluoronaphthalocyanines; C60 and C70 fullerenes; N,N′-dialkyl, substituted dialkyl, diaryl or substituted diaryl-1,4,5,8-naphthalenetetracarboxylic diimide and fluoro derivatives; N,N′-dialkyl, substituted dialkyl, diaryl or substituted diaryl 3,4,9,10-perylenetetracarboxylicdiimide; bathophenanthroline; diphenoquinones; 1,3,4-oxadiazoles; 11,11,12,12-tetracyanonaptho-2,6-quinodimethane; α,α′-bis(di-thieno[3,2-b2′,3′-d]thiophene); 2,8-dialkyl, substituted dialkyl, diaryl or substituted diaryl anthradithiophene; 2,2′-bisbenzo[1,2-b:4,5-b′]dithiophene. Where a liquid deposition technique of the OSC is desired, polymers from the above list and derivatives thereof are limited to those that are soluble in an appropriate solvent or mixture of appropriate solvents.

Further suitable examples of first and second polymers may be selected from the group of polymers comprising a 2,7-(9,9′)spirobifluorene moiety, optionally substituted and preferably substituted with amino groups. Such spirobifluorenes are, for example, disclosed in WO 97/39045. Examples of spirobifluorenes suitable for use as monomeric unit M of formula (I) may be selected from the group consisting of formulae (11-1) to (11-7)

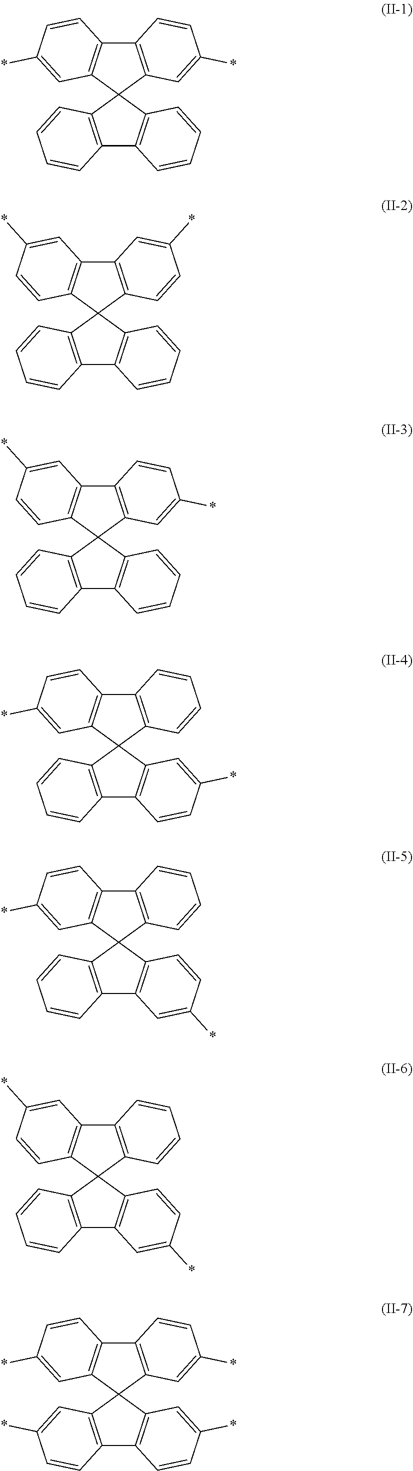

wherein each of the hydrogen atoms may independently of any other be as defined herein in respect to R¹⁰¹ and each asterisk “*” independently may denote a bond to neighboring moiety (for example in a polymer) or may denote a bond to a group as defined above for R¹⁰¹ (for example in a compound of formula (I-a) or (I′)). In respect to formulae (II-1) to (II-7) preferred substituents, including the ones for “*”, may be selected from the group consisting of alkyl having from 1 to 20 carbon atoms; aryl having from 6 to 20 carbon atoms, said aryl being optionally substituted with alkyl or alkoxy having from 1 to 20, preferably 1 to 10 carbon atoms; and NR¹¹⁰R¹¹¹ with R¹¹⁰ and R¹¹¹ being independently of each other selected from the group consisting of alkyl having from 1 to 20 carbon atoms, aryl having from 6 to 20 carbon atoms, said aryl being optionally substituted with alkyl or alkoxy having from 1 to 20, preferably 1 to 10 carbon atoms, most preferably R¹¹⁰ and R¹¹¹ being independently of each other selected from methyl, ethyl, n-propyl, iso-propyl, n-butyl, iso-butyl, tert-butyl, pentyl, methoxy, ethoxy, n-propoxy, iso-propoxy n-butoxy, iso-butoxy, tert-butoxy and pentoxy.

Further preferred first and second polymers are copolymers comprising electron acceptor and electron donor units. Preferred copolymers of this preferred embodiment are for example copolymers comprising one or more benzo[1,2-b:4,5-b′]dithiophene-2,5-diyl units that are preferably 4,8-disubstituted by one or more groups R¹⁰¹ as defined above, and further comprising one or more aryl or heteroaryl units selected from Group A and Group B, preferably comprising at least one unit of Group A and at least one unit of Group B, wherein Group A consists of aryl or heteroaryl groups having electron donor properties and Group B consists of aryl or heteroaryl groups having electron acceptor properties, and preferably

Group A consists of selenophene-2,5-diyl, thiophene-2,5-diyl, thieno[3,2-b]thiophene-2,5-diyl, thieno[2,3-b]thiophene-2,5-diyl, selenopheno[3,2-b]selenophene-2,5-diyl, selenopheno[2,3-b]selenophene-2,5-diyl, selenopheno[3,2-b]thiophene-2,5-diyl, selenopheno[2,3-b]thiophene-2,5-diyl, benzo[1,2-b:4,5-4′]dithiophene-2,6-diyl, 2,2-dithiophene, 2,2-diselenophene, dithieno[3,2-b:2′,3′-d]silole-5,5-diyl, 4H-cyclopenta[2,1-b:3,4-b′]dithiophene-2,6-diyl, 2,7-di-thien-2-yl-carbazole, 2,7-di-thien-2-yl-fluorene, indaceno[1,2-b:5,6-b′]dithiophene-2,7-diyl, benzo[1″,2″:4,5;4″,5″:4′,5′]bis(silolo[3,2-b:3′,2′-b′]thiophene)-2,7-diyl, 2,7-di-thien-2-yl-indaceno[1,2-b:5,6-b′]dithiophene, 2,7-di-thien-2-yl-benzo[1″,2″:4,5;4″,5″:4′,5′]bis(silolo[3,2-b:3′,2′-b′]thiophene)-2,7-diyl, and 2,7-di-thien-2-yl-phenanthro[1,10,9,8-c,d,e,f,g]carbazole, all of which are optionally substituted by one or more, preferably one or two groups R as defined above, and

Group B consists of benzo[2,1,3]thiadiazole-4,7-diyl, 5,6-dialkyl-benzo[2,1,3]thiadiazole-4,7-diyl, 5,6-dialkoxybenzo[2,1,3]thiadiazole-4,7-diyl, benzo[2,1,3]selenadiazole-4,7-diyl, 5,6-dialkoxy-benzo[2,1,3]selenadiazole-4,7-diyl, benzo[1,2,5]thiadiazole-4,7,diyl, benzo[1,2,5]selenadiazole-4,7,diyl, benzo[2,1,3]oxadiazole-4,7-diyl, 5,6-dialkoxybenzo[2,1,3]oxadiazole-4,7-diyl, 2H-benzotriazole-4,7-diyl, 2,3-dicyano-1,4-phenylene, 2,5-dicyano,1,4-phenylene, 2,3-difluro-1,4-phenylene, 2,5-difluoro-1,4-phenylene, 2,3,5,6-tetrafluoro-1,4-phenylene, 3,4-difluorothiophene-2,5-diyl, thieno[3,4-b]pyrazine-2,5-diyl, quinoxaline-5,8-diyl, thieno[3,4-b]thiophene-4,6-diyl, thieno[3,4-b]thiophene-6,4-diyl, and 3,6-pyrrolo[3,4-c]pyrrole-1,4-dione, all of which are optionally substituted by one or more, preferably one or two groups R¹⁰¹ as defined above.

Specific examples of particularly well suited first polymers may be selected from polymers comprising, preferably consisting of, monomeric units M selected from the group consisting of (A6), (D1) and (D22). Such first polymers may, for example, be
(i) polymer (P-1) consisting of monomeric units M of the following formulae (M-1-a) and (M-1-b), preferably in a molar ratio of from 0.9:1 to 1.1:1, or from 0.95:1 to 1.05:1, or
(ii) polymer (P-2) consisting of monomeric units M of the following formula (M-2).

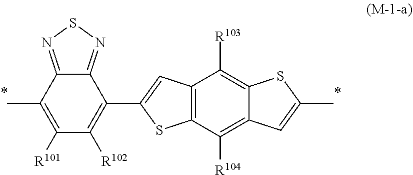

with R¹⁰¹, R¹⁰², R¹⁰³ and R¹⁰⁴ as defined above; and preferably with R¹⁰¹=R¹⁰²=alkoxy having from 1 to 15, preferably from 5 to 10 carbon atoms, and R¹⁰³=R¹⁰⁴=alkyl having from 5 to 20, preferably from 10 to 15 carbon atoms;

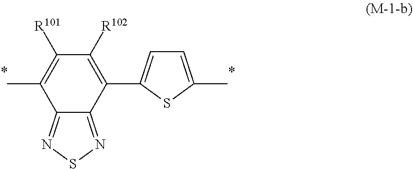

with R¹⁰¹ and R¹⁰² as defined above for (M-1-a);

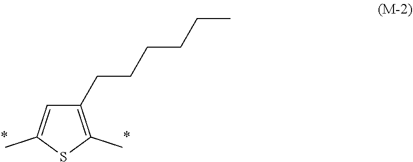

Specific examples of particularly well suited second polymers may be selected from polymers comprising, preferably consisting of, monomeric units M selected from the group consisting of (D19), (D111), (D128) and (D142). Such second polymers may, for example, be represented by the following formulae (P-2), and (P-4).

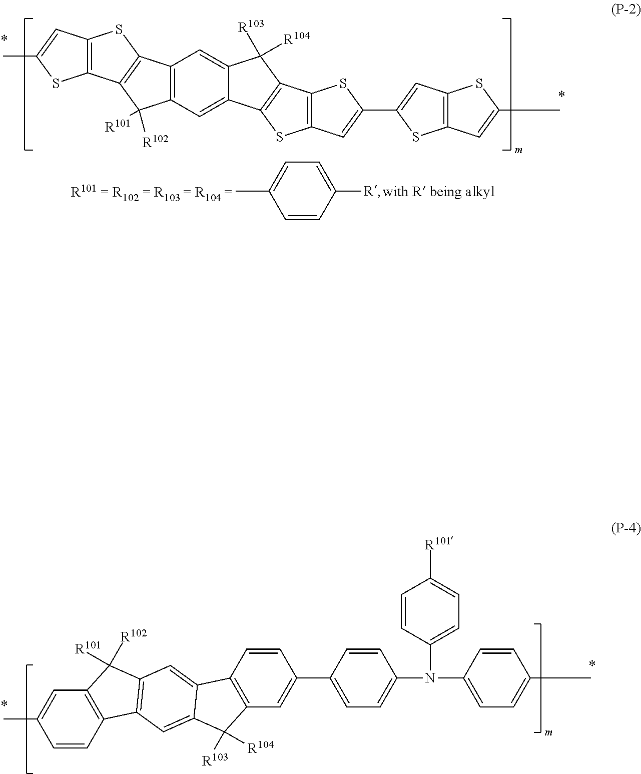

with R¹⁰¹=R¹⁰²=R¹⁰³=R¹⁰⁴ as defined above and preferably being selected from alkyl having from 5 to 20 carbon atoms, with R¹⁰¹′ being as defined for R¹° ¹ and preferably being selected from alkyl having from 1 to 10 carbon atoms.

Further preferred second polymers may be selected from the group consisting of polymers and copolymers of formula (I) wherein M is a tetra-heteroaryl indacenodithiophene-based unit as disclosed in WO 2016/015804 A1, and polymers or copolymers comprising one or more repeating units thereof, such as, for example, one of the following polymers (P-5) to (P-7):

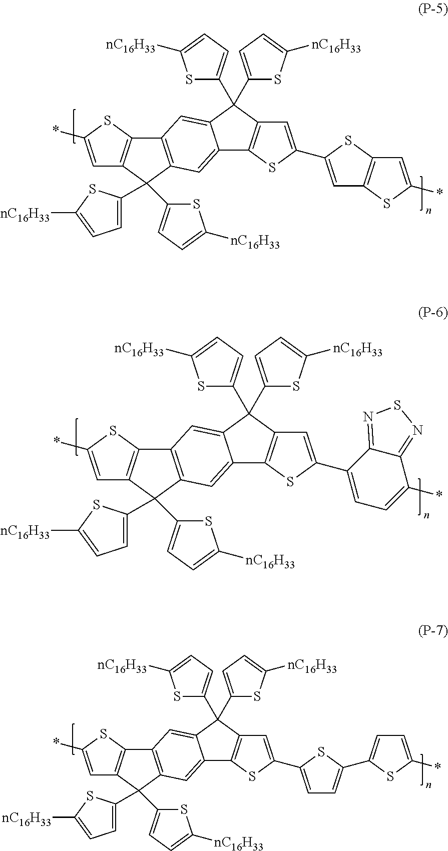

Organic semiconducting polymers as used herein may, for example, be purchased from commercial sources, such as SigmaAldrich or Merck KGaA (Darmstadt, Germany).

Alternatively, organic semiconducting polymers as used herein may be synthesized according to or in analogy to methods that are known to the skilled person and are described in the literature from monomers as described in the following.

Monomers that are suitable for the synthesis of the present oligomers and polymers may be selected from compounds comprising a structural unit of formula (I), for example with m=1, and at least one reactive chemical group R^{c} which may be selected from the group consisting of CI, Br, I, O-tosylate, O-triflate, O-mesylate, O-nonaflate, —SiMe₂F, —SiMeF₂, —O—SO₂Z¹, —B(OZ²)₂, —CZ³=C(Z³)₂, —C≡CH, —C≡CSi(Z¹)₃, —ZnX⁰⁰ and —Sn(Z⁴)₃, preferably —B(OZ²)₂ or —Sn(Z⁴)₃, wherein X⁰⁰ is as defined herein, and Z¹, Z², Z³ and Z⁴ are selected from the group consisting of alkyl and aryl, preferably alkyl having from 1 to 10 carbon atoms, each being optionally substituted with R⁰ as defined herein, and two groups Z² may also together form a cyclic group. Alternatively such a monomer may comprise two reactive chemical groups and is, for example, represented by formula (I′)

R^{c}—M—R^{d} (I′)

wherein M is as defined herein and R^{c} and R^{d} are reactive chemical groups as defined above in respect to R^{c}. Such monomers may generally be prepared according to methods well known to the person skilled in the art.

X⁰⁰ is halogen. Preferably X⁰⁰ is selected from the group consisting of F, Cl and Br.

Most preferably X⁰⁰ is Br.

Preferred aryl-aryl coupling and polymerisation methods used in the processes described herein may, for example, be one or more of Yamamoto coupling, Kumada coupling, Negishi coupling, Suzuki coupling, Stille coupling, Sonogashira coupling, Heck coupling, C—H activation coupling, Ullmann coupling and Buchwald coupling. Especially preferred are Suzuki coupling, Negishi coupling, Stille coupling and Yamamoto coupling. Suzuki coupling is described for example in WO 00/53656 A1. Negishi coupling is described for example in J. Chem. Soc., Chem. Commun., 1977, 683-684. Yamamoto coupling is described for example in T. Yamamoto et al., Prog. Polym. Sci., 1993, 17, 1153-1205, or WO 2004/022626 A1, and Stille coupling is described for example in Z. Bao et al., J. Am. Chem. Soc., 1995, 117, 12426-12435. For example, when using Yamamoto coupling, monomers having two reactive halide groups are preferably used. When using Suzuki coupling, compounds of formula (I′) having two reactive boronic acid or boronic acid ester groups or two reactive halide groups are preferably used. When using Stille coupling, monomers having two reactive stannane groups or two reactive halide groups are preferably used. When using Negishi coupling, monomers having two reactive organozinc groups or two reactive halide groups are preferably used.

Preferred catalysts, especially for Suzuki, Negishi or Stille coupling, are selected from Pd(0) complexes or Pd(II) salts. Preferred Pd(0) complexes are those bearing at least one phosphine ligand, for example Pd(Ph₃P)₄. Another preferred phosphine ligand is tris(ortho-tolyl)phosphine, for example Pd(o-Tol₃P)₄. Preferred Pd(II) salts include palladium acetate, for example Pd(OAc)₂. Alternatively the Pd(0) complex can be prepared by mixing a Pd(0) dibenzylideneacetone complex, for example tris(dibenzylindeneacetone)dipalladium(0), bis(dibenzylideneacetone)-palladium(0), or Pd(II) salts e.g. palladium acetate, with a phosphine ligand, for example triphenylphosphine, tris(ortho-tolyl)phosphine or tri(tert-butyl)phosphine. Suzuki polymerisation is performed in the presence of a base, for example sodium carbonate, potassium carbonate, lithium hydroxide, potassium phosphate or an organic base such as tetraethylammonium carbonate or tetraethylammonium hydroxide. Yamamoto polymerisation employs a Ni(0) complex, for example bis(1,5-cyclooctadienyl)nickel(0).

Suzuki and Stille polymerisation may be used to prepare homopolymers as well as statistical, alternating and block random copolymers. Statistical or block copolymers can be prepared for example from the above monomers of formula (I′), wherein one of the reactive groups is halogen and the other reactive group is a boronic acid, boronic acid derivative group or and alkylstannane. The synthesis of statistical, alternating and block copolymers is described in detail for example in WO 03/048225 A2 or WO 2005/014688 A2.

As alternatives to halogens as described above, leaving groups of formula —O—SO₂Z¹ can be used wherein Z¹ is as described above. Particular examples of such leaving groups are tosylate, mesylate and triflate.

The present photoactive composition also comprises an electron acceptor, e.g. an n-type semiconducting material. The n-type semiconducting material can be an inorganic material such as zinc oxide (ZnOₓ), zinc tin oxide (ZTO), titan oxide (TiOₓ), molybdenum oxide (MoOₓ), nickel oxide (NiOₓ), or cadmium selenide (CdSe), or an organic material such as graphene or a fullerene or a substituted fullerene, for example an indene-C₆₀-fullerene bisaduct like ICBA, or a (6,6)-phenyl-butyric acid methyl ester derivatized methano C₆₀ fullerene, also known as “PCBM-C₆₀” or “C₆₀PCBM”, as disclosed for example in G. Yu, J. Gao, J.C. Hummelen, F. Wudl, A. J. Heeger, Science 1995, Vol. 270, p. 1789 ff and having the structure shown below, or structural analogous compounds with e.g. a C₆₁ fullerene group, a C₇₀ fullerene group, or a C₇₁ fullerene group, or an organic polymer (see for example Coakley, K. M. and McGehee, M. D. Chem. Mater. 2004, 16, 4533).

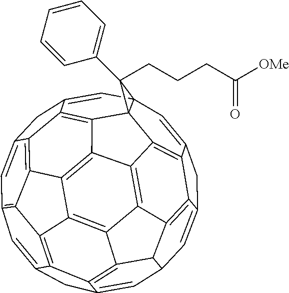 [SMILES: COC(=O)CCCC1(c2ccccc2)C23C=C4CC5=CC6C=C7Cc8cc9cc%10c%11c(c%12c%13c%14c(c4c5c4c%14c5c(c7c8c7c9c%11c%13c57)C46)C%1221)C(=C3)C%10]

Preferably the first and second polymers as defined herein are blended with an n-type semiconducting material such as a fullerene or substituted fullerene, like for example PCBM-C₆₀, PCBM-C₇₀, PCBM-C₆₁, PCBM-C₇₁, bis-PCBM-C₆₁, bis-PCBM-C₇₁, ICMA-c₆₀ (1′,4′-Dihydro-naphtho[2′,3′:1,2][5,6]fullerene-C₆₀), ICBA-C₆₀, oQDM-C₆₀ (1′,4′-dihydro-naphtho[2′,3′:1,9][5,6]fullerene-C60-lh), bis-oQDM-C₆₀, graphene, or a metal oxide, like for example, ZnOₓ, TiOₓ, ZTO, MoOₓ, NiOₓ, or quantum dots like for example CdSe or CdS, to eventually form the active layer in an OPV or OPD device.

Alternatively, instead of the above electron acceptors (or n-type semiconductors) a so-called non-fullerene acceptor may be used.

Non-fullerene acceptors comprise a central polycyclic core and one or more terminal group showing electron withdrawing properties relative to the central polycyclic core, and may optionally further comprise one or more aromatic or heteroaromatic spacer groups that are between the central polycyclic core and the one or more terminal group and that may have electron withdrawing or electron donating properties relative to the central polycyclic core.

Such non-fullerene acceptors preferably have an acceptor-donor-acceptor (A-D-A) structure, wherein the central polycyclic core acts as donor and the terminal groups, optionally together with the aromatic or heteroaromatic spacer groups, acts as acceptor.

Suitable non-fullerene acceptors may be represented by the following formula (VII)

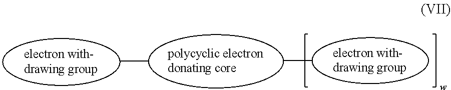

wherein w is 0 or 1.

Examples of suitable non-fullerene acceptors are, for example, disclosed in Y. Lin, J. Wang, Z.-G. Zhang, H. Bai, Y. Li, D. Zhu and X. Zhan, Adv. Mater. 2015, 27, 1170-1174; in H. Lin, S. Chen, Z. Li, J. Y. L. Lai, G. Yang, T. McAfee, K. Jiang, Y. Li, Y. Liu, H. Hu, J. Zhao, W. Ma, H. Ade and H. Yan, Zhan, Adv. Mater., 2015, 27, 7299; in WO 2018/007479 A1, WO 2018/036914 A1, WO 2018/065350 A1, WO 2018/065352 A1, WO 2018/065356 A1 and EP 3306690 A1.

The present photoactive composition can additionally comprise one or more further components or additives selected for example from surface-active compounds, lubricating agents, wetting agents, dispersing agents, hydrophobing agents, adhesive agents, flow improvers, defoaming agents, deaerators, diluents which may be reactive or non-reactive, auxiliaries, colorants, dyes or pigments, sensitizers, stabilizers, nanoparticles or inhibitors.

### Formulation

The present application also relates to a photoactive formulation comprising an organic solvent and the photoactive composition as defined herein.

Preferred organic solvents are aliphatic hydrocarbons, chlorinated hydrocarbons, aromatic hydrocarbons, ketones, ethers and mixtures thereof. Additional solvents which can be used include 1,2,4-trimethylbenzene, 1,2,3,4-tetra-methyl benzene, pentylbenzene, mesitylene, cumene, cymene, cyclohexylbenzene, diethylbenzene, tetralin, decalin, 2,6-lutidine, 2-fluoro-m-xylene, 3-fluoro-o-xylene, 2-chlorobenzotrifluoride, N,N-dimethylformamide, 2-chloro-6-fluorotoluene, 2-fluoroanisole, anisole, 2,3-dimethylpyrazine, 4-fluoroanisole, 3-fluoroanisole, 3-trifluoro-methylanisole, 2-methylanisole, phenetol, 4-methylanisole, 3-methylanisole, 4-fluoro-3-methylanisole, 2-fluorobenzonitrile, 4-fluoroveratrol, 2,6-dimethylanisole, 3-fluorobenzo-nitrile, 2,5-dimethylanisole, 2,4-dimethylanisole, benzonitrile, 3,5-dimethyl-anisole, N,N-dimethylaniline, ethyl benzoate, 1-fluoro-3,5-dimethoxy-benzene, 1-methylnaphthalene, N-methylpyrrolidinone, 3-fluorobenzo-trifluoride, benzotrifluoride, dioxane, trifluoromethoxy-benzene, 4-fluorobenzotrifluoride, 3-fluoropyridine, toluene, 2-fluoro-toluene, 2-fluorobenzotrifluoride, 3-fluorotoluene, 4-isopropylbiphenyl, phenyl ether, pyridine, 4-fluorotoluene, 2,5-difluorotoluene, 1-chloro-2,4-difluorobenzene, 2-fluoropyridine, 3-chlorofluoro-benzene, 1-chloro-2,5-difluorobenzene, 4-chlorofluorobenzene, chloro-benzene, o-dichlorobenzene, 2-chlorofluorobenzene, p-xylene, m-xylene, o-xylene or mixture of o-, m-, and p-isomers. Organic solvents with relatively low polarity are generally preferred. For inkjet printing solvents and solvent mixtures with high boiling temperatures are preferred. For spin coating alkylated benzenes like xylene and toluene are preferred.

Examples of especially preferred organic solvents include, without limitation, dichloromethane, trichloromethane, chlorobenzene, o-dichlorobenzene, tetrahydrofuran, anisole, morpholine, toluene, o-xylene, m-xylene, p-xylene, 1,4-dioxane, acetone, methylethylketone, 1,2-dichloroethane, 1,1,1-trichloroethane, 1,1,2,2-tetrachloroethane, ethyl acetate, n-butyl acetate, N,N-dimethylformamide, dimethylacetamide, dimethylsulfoxide, tetraline, decaline, indane, methyl benzoate, ethyl benzoate, mesitylene and/or mixtures thereof.

Examples of suitable solvents include 1,5-dimethyltetralin and 1,2-dichlorobenzene.

In some embodiments, the overall concentration of electron donor and electron acceptor (i.e. when taken together) in the present photoactive formulation is preferably at least 1 mg/ml (for example at least 2 mg/ml, or 3 mg/ml, or 4 mg/ml, or 5 mg/ml, or 6 mg/ml, or 7 mg/ml, or 8 mg/ml, or 9 mg/ml), more preferably at least 10 mg/ml (for example at least 11 mg/ml, or 12 mg/ml, or 13 mg/ml, or 14 mg/ml, or 15 mg/ml, or 16 mg/ml, or 17 mg/ml, or 18 mg/ml, or 19 mg/ml), even more preferably at least 20 mg/ml (for example at least 21 mg/ml, or 22 mg/ml, or 23 mg/ml, or 24 mg/ml, or 25 mg/ml, or 26 mg/ml, or 27 mg/ml, or 28 mg/ml, or 29 mg/ml), and most preferably at least 30 mg/ml (for example at least 31 mg/ml, or 32 mg/ml, or 33 mg/ml, or 34 mg/ml, or 35 mg/ml, or 36 mg/ml, or 37 mg/ml, or 38 mg/ml, or 39 mg/ml).

The maximum overall concentration of electron donor and electron acceptor (i.e. when taken together) in the present photoactive formulation is not particularly limited and only limited by the solubility of the respective electron donor and electron acceptor. It is, however, preferred that the overall concentration of electron donor and electron acceptor in the present photoactive formulation is, for example, at most 500 mg/ml or 400 mg/ml or 300 mg/ml or 200 mg/ml or 100 mg/ml or 50 mg/ml.

The addition of the second polymer allows to adapt the viscosity of the present photoactive formulation as needed, for example by increasing it. While generally a photoactive formulation comprising a first polymer but not a second polymer will have a viscosity of, for example, 5 cP to 15 cP, the addition of a certain amount of second polymer can help to increase the viscosity from the lower part of such range to the higher part of such range. Alternatively, the viscosity of the photoactive formulation may be increased to, for example, 20 cP or 22 cP or 24 cP or even higher.

The present photoactive formulations may be deposited by any suitable method. Liquid coating is more desirable than vacuum deposition techniques. Solution deposition methods are especially preferred. The formulations of the present invention enable the use of a number of liquid coating techniques. Preferred deposition techniques include, without limitation, dip coating, spin coating, ink jet printing, nozzle printing, letter-press printing, screen printing, gravure printing, doctor blade coating, roller printing, reverse-roller printing, offset lithography printing, dry offset lithography printing, flexographic printing, web printing, spray coating, curtain coating, brush coating, slot dye coating or pad printing.

Ink jet printing is particularly preferred when high resolution layers and devices need to be prepared. Selected formulations of the present invention may be applied to prefabricated device substrates by ink jet printing or microdispensing. Preferably, industrial piezoelectric print heads such as but not limited to those supplied by Aprion, Hitachi-Koki, InkJet Technology, On Target Technology, Picojet, Spectra, Trident, Xaar may be used to apply the organic semiconductor layer to a substrate. Additionally semi-industrial heads such as those manufactured by Brother, Epson, Konica, Seiko Instruments Toshiba TEC or single nozzle microdispensers such as those produced by Microdrop and Microfab may be used.

In order to be applied by ink jet printing or microdispensing, the photoactive composition should be first dissolved in a suitable solvent. Solvents must not have any detrimental effect on the selected print head. Additionally, solvents should have boiling points >100° C., preferably >140° C. and more preferably >150° C. in order to prevent operability problems caused by the solution drying out inside the print head. Apart from the solvents mentioned above, suitable solvents include substituted and non-substituted xylene derivatives, di-C₁₋₂-alkyl formamide, substituted and non-substituted anisoles and other phenol-ether derivatives, substituted heterocycles such as substituted pyridines, pyrazines, pyrimidines, pyrrolidinones, substituted and non-substituted N,N-di-C₁₋₂-alkylanilines and other fluorinated or chlorinated aromatics.

A preferred solvent for depositing a compound or polymer by ink jet printing comprises a benzene derivative which has a benzene ring substituted by one or more substituents. For example, the benzene derivative may be substituted with a propyl group or three methyl groups. Such a solvent enables an ink jet fluid to be formed comprising the solvent with the present photoactive composition, which reduces or prevents clogging of the jets and separation of the components during spraying. The solvent(s) may include those selected from the following list of examples: dodecylbenzene, 1-methyl-4-tert-butylbenzene, terpineol, limonene, isodurene, terpinolene, cymene, diethylbenzene. The solvent may be a solvent mixture, that is a combination of two or more solvents, each solvent preferably having a boiling point >100° C., more preferably >140° C. Such solvent(s) also enhance film formation in the layer deposited and reduce defects in the layer.

An ink jet formulation preferably has a viscosity at 20° C. of 1 mPas to 100 mPa·s, more preferably of 1 mPa·s to 50 mPa·s, and most preferably of 1 mPa·s to 30 mPa·s.

### Devices and Device Fabrication

The present application also relates to an organic photodetector (OPD) or an organic photovoltaic cell (OPV), comprising (preferably in this sequence): an anode, an optional electron transport layer (ETL), a photoactive layer, an optional hole transport layer (HTL), and a cathode; wherein the photoactive layer consists of the photoactive composition as defined herein.

In some embodiments the photoactive layer has a thickness of at least 400 nm to at most 1500 nm; preferably at least 500 nm to at most 1200 nm; more preferably at least 600 nm to at most 1100 nm, for example 800 nm, for example 1000 nm.

The optional transport layers are based on materials which have the capability of being able to primarily transfer either electrons or holes due to suitable positioning of the energy levels. Such transport layers may act as hole transport layer and/or electron blocking layer and comprise a material such as metal oxide, like for example, ZTO, MoOₓ, NiOₓ, a conjugated polymer electrolyte, like for example PEDOT:PSS, a conjugated polymer, like for example polytriarylamine (PTAA), an organic compound, like for example N,N′-diphenyl-N,N′-bis(1-naphthyl)(1,1′-biphenyl)-4,4′diamine (NPB), N,NT-diphenyl-N,NT-(3-methylphenyl)-1,1T-biphenyl-4,4T-diamine (TPD), or alternatively as hole blocking layer and/or electron transporting layer, which comprise a material such as metal oxide, like for example, ZnOₓ, TiOₓ, a salt, like for example LiF, NaF, CsF, a conjugated polymer electrolyte, like for example poly[3-(6-trimethylammoniumhexyl)thiophene], poly(9,9-bis(2-ethylhexyl)-fluorene]-b-poly[3-(6-trimethylammoniumhexyl)thio-phene], or poly[(9,9-bis(3″-(N,N-dimethyl-amino)propyl)-2,7-fluorene)-alt-2,7-(9,9-dioctylfluorene)] or an organic compound, like for example tris(8-quinolinolato)-aluminium(III) (Alq₃), 4,7-diphenyl-1,10-phenanthroline

The most commonly used electrode material is indium tin oxide (ITO), due to a high optical transmission combined with a low resistance. Alternatively, doped PEDOT:PSS allows for easier fabrication on flexible substrates, since the polymer based films have a better tolerance towards bending compared to an ITO electrode. The skilled person will understand that the present application is not limited to a specific electrode material.

OPV and OPD devices are often divided into two groups based on the stack geometry, a regular and an inverted geometry. The definition of the two geometries lies within the direction of the charge flow. In a normal geometry device the substrate and the transparent electrode on it is the positive electrode, with the light passing through the substrate and this electrode before being absorbed in the active layer. The top electrode is then the negative electrode. In the inverted geometry the two electrodes and the charge selective layers are switched around, such that the transparent electrode at the substrate is the negative electrode, with an ETL layer between it and the active layer, while the top electrode is the positive electrode with an HTL layer between it and the active layer. In regular cells typically the anode is ITO and the cathode is a metal with a lower work function than ITO. In the case of inverted cells, the cathode is ITO and the anode is a metal with a work function higher than ITO. The skilled person will understand that the present application is not limited to a specific geometry.

When making OPV and OPD devices the substrates used for supporting the layered stack, can be divided into two distinct groups: glass and plastics. The two most commonly used types being floated glass substrates with ITO transparent electrodes used in lab scale production and flexible PET foil used in upscaling focused on manufacturing, where the transparent electrodes are either ITO as for the glass substrates or printed transparent electrodes. The skilled person will understand that the present application is not limited to a specific substrate material. Dear inventors, please provide a list of suitable substrate materials.

To produce thin layers in BHJ OPV devices the compounds, polymers, polymer blends or formulations of the present invention may be deposited by any suitable method. Liquid coating of devices is more desirable than vacuum deposition techniques. Solution deposition methods are especially preferred. The formulations of the present invention enable the use of a number of liquid coating techniques. Preferred deposition techniques include, without limitation, dip coating, spin coating, ink jet printing, nozzle printing, letter-press printing, screen printing, gravure printing, doctor blade coating, roller printing, reverse-roller printing, offset lithography printing, dry offset lithography printing, flexographic printing, web printing, spray coating, curtain coating, brush coating, slot dye coating or pad printing. For the fabrication of OPV and OPD devices and modules area printing methods compatible with flexible substrates are preferred, for example slot dye coating, spray coating and the like.

Suitable solutions or formulations containing the blend or mixture of a polymer according to the present invention with a C₆₀ or C₇₀ fullerene or modified fullerene like PCBM must be prepared. In the preparation of formulations, suitable solvent must be selected to ensure full dissolution of both component, p-type and n-type and take into account the boundary conditions (for example rheological properties) introduced by the chosen printing method.

Organic solvents are generally used for this purpose. Typical solvents can be aromatic solvents, halogenated solvents or chlorinated solvents, including chlorinated aromatic solvents. Examples include, but are not limited to chlorobenzene, 1,2-dichlorobenzene, chloroform, 1,2-dichloroethane, dichloromethane, carbon tetrachloride, toluene, cyclohexanone, ethylacetate, tetrahydrofuran, anisole, morpholine, o-xylene, m-xylene, p-xylene, 1,4-dioxane, acetone, methylethylketone, 1,2-dichloroethane, 1,1,1-trichloroethane, 1,1,2,2-tetrachloroethane, ethyl acetate, n-butyl acetate, dimethylformamide, dimethylacetamide, dimethylsulfoxide, tetraline, decaline, indane, methyl benzoate, ethyl benzoate, mesitylene and combinations thereof.

The OPV device can for example be of any type known from the literature (see e.g. Waldauf et al., Appl. Phys. Lett., 2006, 89, 233517).

A first preferred OPV device according to the invention comprises the following layers (in the sequence from bottom to top):
optionally a substrate,
a high work function electrode, preferably comprising a metal oxide, like for example ITO, serving as anode,
an optional conducting polymer layer or hole transport layer, preferably comprising an organic poymer or polymer blend, for example of PEDOT:PSS (poly(3,4-ethylenedioxythiophene):poly(styrene-sulfonate), or TBD (N,N′-dyphenyl-N-N′-bis(3-methylphenyl)-1,1′biphenyl-4,4′-diamine) or NBD (N,N′-dyphenyl-N-N′-bis(1-napthylphenyl)-1,1′biphenyl-4,4′-diamine),
a layer, also referred to as “active layer”, comprising a p-type and an n-type organic semiconductor, which can exist for example as a p-type/n-type bilayer or as distinct p-type and n-type layers, or as blend or p-type and n-type semiconductor, forming a BHJ,
optionally a layer having electron transport properties, for example comprising LiF,
a low work function electrode, preferably comprising a metal like for example aluminum, serving as cathode,
   wherein at least one of the electrodes, preferably the anode, is transparent to visible light, and wherein the p-type semiconductor is a polymer according to the present invention.

A second preferred OPV device according to the invention is an inverted OPV device and comprises the following layers (in the sequence from bottom to top):
optionally a substrate,
a high work function metal or metal oxide electrode, comprising for example ITO, serving as cathode,
a layer having hole blocking properties, preferably comprising a metal oxide like TiOₓ or Znₓ,
an active layer comprising a p-type and an n-type organic semiconductor, situated between the electrodes, which can exist for example as a p-type/n-type bilayer or as distinct p-type and n-type layers, or as blend or p-type and n-type semiconductor, forming a BHJ,
an optional conducting polymer layer or hole transport layer, preferably comprising an organic polymer or polymer blend, for example of PEDOT:PSS or TBD or NBD,
an electrode comprising a high work function metal like for example silver, serving as anode,
   wherein at least one of the electrodes, preferably the cathode, is transparent to visible light, and wherein the p-type semiconductor is a polymer according to the present invention.

In the OPV and OPD devices of the present invention the p-type and n-type semiconductor materials are preferably selected from the materials, like the polymer/fullerene systems, as described above

When the active layer is deposited on the substrate, it forms a BHJ that phase separates at nanoscale level. For discussion on nanoscale phase separation see Dennler et al, Proceedings of the IEEE, 2005, 93 (8), 1429 or Hoppe et al, Adv. Func. Mater, 2004, 14(10), 1005. An optional annealing step may be then necessary to optimize blend morphology and consequently OPV device performance.

Another method to optimize device performance is to prepare formulations for the fabrication of OPV(BHJ) and OPD devices that may include high boiling point additives to promote phase separation in the right way. 1,8-Octanedithiol, 1,8-diiodooctane, nitrobenzene, chloronaphthalene, and other additives have been used to obtain high-efficiency solar cells. Examples are disclosed in J. Peet, et al, Nat. Mater., 2007, 6, 497 or Fréchet et al. J. Am. Chem. Soc., 2010, 132, 7595-7597.

Thus, the present application also relates to a method for preparing an organic photodetector (OPD) or an organic photovoltaic cell (OPV), said process comprising the steps of
(a) providing a first electrode on a substrate;
(b) optionally forming an electron transport layer (ETL) on the electrode;
(c) subsequently depositing a photoactive formulation as defined herein on the electrode and removing the organic solvent, thereby obtaining a photoactive layer consisting of the photoactive composition as defined herein;
(d) optionally forming a hole transporting layer (HTL) on the photoactive layer; and
(e) subsequently forming the second electrode.

### EXAMPLES

To better illustrate the properties, advantages and features of the present application some preferred embodiments are disclosed in a non-limiting way as examples.

Polymers P1 to P4 as defined above were synthesized in accordance with well known methods by Stille polymerization from the respective monomers.

### Example 1

A copolymer of alkylsubstituted benzodithiophene, thiophene and substituted benzothiadiazole having a low weight average molecular weight M_{W} and a band gap E_{g} of ca. 1.7 eV was used as low band gap polymer P1.

A copolymer of an aryl-substituted indacenobisdithiophene and a dithiophene having a high weight average molecular weight M_{w} and a band gap E_{g} of ca. 2.2 eV was used a high band gap polymer P2.

Four photoactive formulations in 1,5-dimethyltetralin with 28 mg/ml of PCBM-C60 and a total polymer content of polymers P1 and P2 of 14 mg/ml with the respective content of P2 of 0 mg/ml (as comparative example), 2 mg/ml, 4 mg/ml and 7 mg/ml were prepared (see Table 1).

TABLE 1

| | P1 | P2 | PCBM-C₆₀ |
|---|---|---|---|
| Example | [mg/ml] | [mg/ml] | [mg/ml] |
| 1 (Comparative) | 14 | 0 | 28 |
| 2 | 12 | 2 | 28 |
| 3 | 10 | 4 | 28 |
| 4 | 7 | 7 | 28 |

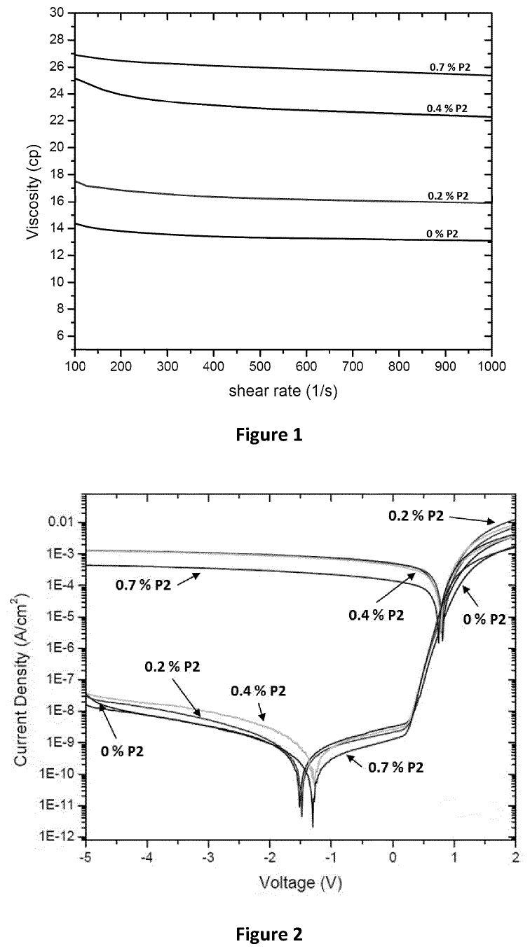

The viscosities of these formulations were measured at shear rates between 200 and 1000 1/s. The results are presented in FIG. 1. The mixed formulations comprising a wt. ratio of 1:1 of P1 and P2 (Example 4) and 2.5:1 of P1 and P2 (Example 3) show a viscosity above 20 cP, in comparison with the viscosity of 13-14 cP for the comparative example (Example 1).

OPD devices were prepared in standard lab atmosphere from each of the four different formulations of Table 1 as described in the following steps (1) to (5):
(1) Substrate cleaning—The substrates used were pre-patterned ITO substrates consisting of 6 patterned ITO dots with a diameter of 5 mm, and a narrow ITO strip connecting the dot to pads on the substrate edge for diode connection. The substrates were placed in a beaker using a Teflon holder, and sonicated consecutively in acetone, isopropanol, and water for 5 min before finally rinsing using a spin rinse dryer.
(2) Electron transport layer (ETL)—The ETL was solution processed ZnO. The ETL was deposited from an ethanol based solution by spin coating with a speed of 4000 rpm for 60 s, and dried on a hot plate at 100-140° C. for 10 min.
(3) Active layer—The photoactive formulation for the BHJ layer was deposited using a K101 Control Coater System from RK. The stage temperature was set at 70° C., the gap between blade and substrate was set to 10-50 μm, and the speed was set to 40 mm/s, to achieve an active layer of 1 μm thickness. The active layer was annealed at 120° C. for 10 min.
(4) Hole transport layer (HTL)—The HTL was MoO₃ deposited using the e-beam evaporation method. The deposition was carried out by using a Lesker evaporator. The vacuum was 10⁻⁷ Torr and the evaporation rate was 0.1 A/S to achieve a final thickness between 5 nm and 30 nm.
(5) Top electrode—For the top electrode Ag was deposited by thermal evaporation through a shadow mask, to achieve a thickness of 40 nm to 80 nm.

The device performance was assessed by measuring the IV (i.e. current/voltage) curve from −5V to 2V in dark and light conditions (580 nm LED lamp at 0.3 mW/cm²).

The results are presented in FIG. 2. No significant difference between the four OPD devices could be found, and the ratio of polymers P1 and P2 seems to have no negative effect on the electrical properties of the OPD device.

As a general conclusion, it was demonstrated that a mixture comprising a low band gap polymer and a high band gap polymer contributes to a higher viscosity value without compromising the performance of the OPD device.

### Example 2

P3HT having a low weight average molecular weight M_{w} of 36,000 g mol⁻¹ and a band gap E_{g} of 2.0 eV was used as low band gap polymer P3.

A copolymer of an alkyl-substituted indenofluorene and triarylamine-based monomeric units with a high weight average molecular weight Mw of 200,000 g mol⁻¹ and a band gap E_{g} of 2.8 eV as high band gap polymer P4.

Four photoactive formulations in 1,2-dichlorobenzene (DCB) with 20 mg/ml of PCBM-C₆₀ and a total polymer content of polymers P3 and P4 of 10 mg/ml with the respective content of P4 of 0 mg/ml (as comparative example), 1 mg/ml, 3 mg/ml and 5 mg/ml were prepared (see Table 2).

TABLE 2

| | P3 | P4 | PCBM-C₆₀ |
|---|---|---|---|
| Example | [mg/ml] | [mg/ml] | [mg/ml] |
| 5 (Comparative) | 10 | 0 | 20 |
| 6 | 9 | 1 | 20 |
| 7 | 7 | 3 | 20 |
| 8 | 5 | 5 | 20 |

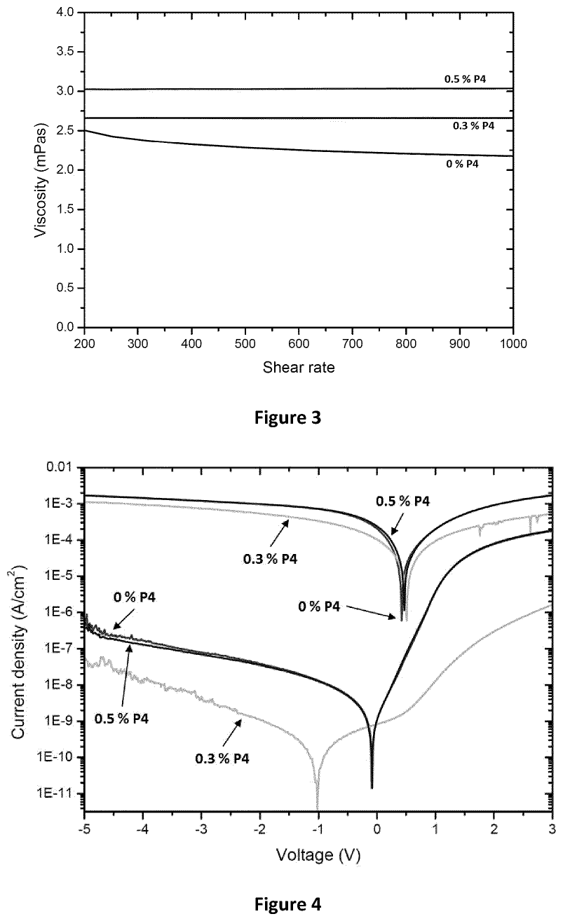

The viscosities of the above mentioned formulations were measured at shear rates between 200 and 1000 1/s. The results are presented in FIG. 3. The mixed formulations of Example 8 comprising a wt. ratio of 1:1 between polymers P3 and P4 shows a viscosity above 3.0 mPas, in comparison with the viscosity of below 2.5 mPas for comparative example 5 when only P3 is used.

OPD devices were prepared and their performance determined as described in respect to Example 1 above. The respective IV curves are shown in FIG. 4. The curves clearly show that the addition of a high band gap polymer does not lead to a reduction in device performance.

The observations of Example 2 thus confirm the general conclusion of Example 1. In general, the results of Examples 1 and 2 show that the addition of a high band gap polymer to a low band gap polymer allows to adapt the viscosities of photoactive formulation and tailor-make them to use in various deposition methods, such as for example, various printing methods, while at the same time not resulting in reduced device performance.

Thus, the present application allows adaptation of the respective photoactive formulations to various deposition techniques, particularly to large scale deposition and coating techniques. Very surprisingly, the photoactive layers having been produced from the present photoactive formulations show very little to no diminishing electrical properties. Thus, the addition of the second polymer, i.e. the high band gap polymer, does not—or at least not significantly—compromise the performance of the OPD device wherein said photoactive formulation is used to form the photoactive layer.

The present application therefore addresses the drawback that conventional OPD and OPV polymers may exhibit low viscosity, which limits their suitability for various deposition techniques, particularly those that require high viscosity.

In contrast, in the field of organic thin film transistors (OTFT), high band gap polymers are typically used as semiconductor material. These OTFT polymers typically have relatively long carbon side chains, which make them generally more soluble in a wider range of solvents and also achieve higher viscosity value. However, their insulating properties make them unsuitable for use as a photoactive layer material (e.g. insufficient photon capture and charge transfer).

1. A photoactive composition comprising an electron donor and an electron acceptor, with the electron donor comprising at least a first organic semiconducting polymer and at least a second organic semiconducting polymer that is different from the first organic semiconducting polymer, wherein the first organic semiconducting polymer and the second organic semiconducting polymer have a difference in band gap (ΔE_{g}) of at least 0.20 eV, with band gaps determined by optical absorption.

2. The photoactive composition of claim 1, wherein the difference in band gap is at least 0.30 eV.

3. The photoactive composition according to claim 1, wherein the first organic semiconducting polymer has a band gap E_{g} of at most 2.05 eV.

4. The photoactive composition according to claim 1, wherein the first organic semiconducting polymer has a band gap E_{g} of at least 0.5 eV.

5. The photoactive composition according to claim 1, wherein the second organic semiconducting polymer has a band gap E_{g} of at least 2.15 eV.

6. The photoactive compositions according to claim 1, wherein the second organic semiconducting polymer has a band gap E_{g} of at most 5.0 eV.

7. The photoactive composition according to claim 1, wherein the first organic semiconducting polymer has a weight average molecular weight (M_{w}) of at least 5,000 g mol⁻¹, determined by GPC.

8. The photoactive composition according to claim 1, wherein the first organic semiconducting polymer has a weight average molecular weight (M_{w}) of at most 120,000 g mol⁻¹, determined by GPC.

9. The photoactive composition according to claim 1, wherein the second organic semiconducting polymer has a weight average molecular weight (M_{w}) of at least 130,000 g mol⁻¹, determined by GPC.

10. The photoactive composition according to claim 1, wherein the second organic semiconducting polymer has a weight average molecular weight (M_{w}) of at most 1,000,000 g mol⁻¹, determined by GPC.

11. The photoactive composition according to claim 1, wherein the first organic semiconducting polymer and the second organic semiconducting polymer have a difference in weight average molecular weight (ΔM_{w}) of at least 50,000 g mol⁻¹, with molecular weights determined by GPC.

12. The photoactive composition according to a claim 1, wherein the first organic semiconducting polymer and the second organic semiconducting polymer have a difference in weight average molecular weight (ΔM_{w}) of at most 50,000 g mol⁻¹, with molecular weights determined by GPC.

13. The photoactive composition according to claim 1, wherein the weight ratio of the first organic semiconducting polymer to the second organic semiconducting polymer is at least 1:1 to at most 10:1.

14. A photoactive formulation comprising an organic solvent and the photoactive composition of according to claim 1.

15. An organic photodetector device (OPD) or organic photovoltaic device (OPV), comprising
an anode,
an optional electron transport layer (ETL),
a photoactive layer,
an optional hole transport layer (HTL), and
a cathode,
wherein the photoactive layer comprises the photoactive composition according to claim 1.

16. A method for preparing an organic photodetector (OPD) or an organic photovoltaic cell (OPV), said process comprising the steps of
(a) providing a first electrode on a substrate;
(b) optionally forming an electron transport layer (ETL) on the electrode;
(c) subsequently depositing a photoactive formulation comprising an organic solvent and the photoactive composition according to claim 1 on the electrode and removing the organic solvent, thereby obtaining a photoactive layer consisting of the photoactive composition according to claim 1;
(d) optionally forming a hole transporting layer (HTL) on the photoactive layer; and
(e) subsequently forming the second electrode.
